(19) United States
(12) Patent Application Publication
(10) Pub. No.: US 2026/0107478 A1
(43) Pub. Date: Apr. 16, 2026

(54) THREE-DIMENSIONAL MEMORY DEVICES AND FABRICATING METHODS THEREOF

(71) Applicant: YANGTZE MEMORY TECHNOLOGIES CO., LTD., Wuhan (CN)

(72) Inventors: Zongliang Huo, Wuhan (CN); Yi Zhao, Wuhan (CN); Liang Xiao, Wuhan (CN); Zhengliang Xia, Wuhan (CN); Quan Zhang, Wuhan (CN); Liang Chen, Wuhan (CN); Yanwei Shi, Wuhan (CN)

(21) Appl. No.: 18/937,898

(22) Filed: Nov. 5, 2024

Related U.S. Application Data
(63) Continuation of application No. PCT/CN2024/124066, filed on Oct. 11, 2024.

(51) Int. Cl. H10B 80/00; H01L 23/00; H01L 25/00; H01L 25/065; H01L 25/18

(52) U.S. Cl. CPC H10B 80/00; H10W 90/00; H10W 80/312; H10W 80/327; H10W 90/297; H10W 90/792

(57) ABSTRACT

Three-dimensional (3D) memory devices and fabricating methods thereof are disclosed. In certain aspects, a memory device comprises: a first semiconductor structure comprising an array of memory cells; and a second semiconductor structure including peripheral circuits on the first semiconductor structure. The second semiconductor structure comprises: transistors at a first side of a semiconductor layer, first isolation structures in the semiconductor layer and between the transistors, an insulating structure in the semiconductor layer and on a lateral side of the transistors, a second isolation structure in the semiconductor layer and surrounding the first isolation structures and the insulating structure, and a through interconnect structure extending through the insulating structure.

### CROSS-REFERENCE TO RELATED APPLICATIONS

This application is a continuation of International Application No. PCT/CN2024/124066, filed on Oct. 11, 2024, which is hereby incorporated by reference in its entirety.

### TECHNICAL FIELD

The present disclosure generally relates to the field of semiconductor technology, and more particularly, to three-dimensional (3D) memory devices and fabricating methods thereof.

### BACKGROUND

With continuous rising and development of artificial intelligence (AI), big data, Internet of Things, mobile devices and communications, and cloud storage, etc., the demand for memory capacity are growing in an exponential way.

Planar memory devices are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral devices for controlling signals to and from the memory array.

### SUMMARY

One aspect of the present disclosure provides a memory device, comprising: a first semiconductor structure comprising an array of memory cells; and a second semiconductor structure including peripheral circuits on the first semiconductor structure, and comprising: transistors at a first side of a semiconductor layer, first isolation structures in the semiconductor layer and between the transistors, an insulating structure in the semiconductor layer and on a lateral side of the transistors, a second isolation structure in the semiconductor layer and surrounding the first isolation structures and the insulating structure, and a through interconnect structure extending through the insulating structure.

In some implementations, the first semiconductor structure further comprises a first interconnect layer comprising first interconnect structures coupled with the array of memory cells; and the second semiconductor structure further comprises a second interconnect layer comprising second interconnect structures coupled with the transistors and the through interconnect structure.

In some implementations, the first semiconductor structure is hybrid bonded with the second semiconductor structure in a vertical direction; and the first interconnect structures are coupled with the second interconnect structures and the through interconnect structure.

In some implementations, the memory device further comprises: a pad-out structure on a second side of the semiconductor layer distant from the first semiconductor structure, and comprising a conductive pad coupled with the through interconnect structure; wherein the transistors are on a first side of the semiconductor layer close to the first semiconductor structure.

In some implementations, a first depth of the first isolation structures is less than a second depth of the second isolation structure.

In some implementations, the memory device further comprises: the semiconductor layer comprises a doped sublayer and an undoped sublayer; and the first isolation structures are embedded in the doped sublayer.

In some implementations, the through interconnect structure comprises: a first contact structure extending into a stack structure from a first side close to the first semiconductor structure; and a via contact extending through the semiconductor layer and extending into the stack structure from a second side opposite to the first side, and in contact with the first contact structure.

In some implementations, the stack structure comprises: a TiN layer; and a SiN layer.

In some implementations, the second semiconductor structure further comprises: a second contact structure extending through the SiN layer without extending through the TiN layer.

In some implementations, the through interconnect structure comprises: a first contact portion between the insulating structure and the first interconnect layer; a via portion extending through the insulating structure, and in contact with the first contact portion; and a second contact portion between the semiconductor layer and the second interconnect layer, and in contact with the via portion; wherein side surfaces of the first contact portion, the via portion, and the second contact portion have offsets.

In some implementations, the pad-out structure further comprises: a third interconnect layer comprising third interconnect structures coupled between the conductive pad and the through interconnect structure.

In some implementations, the first semiconductor structure is a 3D NAND array comprising an array of vertical NAND memory strings.

In some implementations, the first semiconductor structure is a DRAM memory cells array comprising an array of vertical transistors and vertical capacitors.

In some implementations, the insulating structure comprises a protecting layer laterally surrounding the through interconnect structure and an insulating layer laterally surrounding the protecting layer.

In some implementations, the insulating structure comprises silicon oxide; and the protecting layer comprises silicon nitride.

In some implementations, a lateral dimension of a first end of the through interconnect structure close to the transistors is less than a lateral dimension of a second end of the through interconnect structure distant from the transistors.

In some implementations, the second semiconductor structure further comprises: a transistor contact on the first side of the semiconductor layer, wherein a lateral dimension of a first end of the transistor contact in contact with the transistors is less than a lateral dimension of a second end of the transistor contact distant from the transistors.

Another aspect of the present disclosure provides a memory device, comprising: a first semiconductor structure comprising an array of memory cells; and a second semiconductor structure including peripheral circuits on the first semiconductor structure, and comprising: transistors at a first side of a semiconductor layer, first isolation structures in the semiconductor layer and between the transistors, an insulating structure extending through the semiconductor layer and on a lateral side of the transistors, and a stack structure, and a through interconnect structure extending through the insulating structure and the stack structure.

In some implementations, the first semiconductor structure further comprises a first interconnect layer comprising first interconnect structures coupled with the array of memory cells; and the second semiconductor structure further comprises a second interconnect layer comprising second interconnect structures coupled with the transistors and the through interconnect structure.

In some implementations, the first semiconductor structure is hybrid bonded with the second semiconductor structure in a vertical direction, and the first interconnect structures are coupled with the second interconnect structures and the through interconnect structure.

In some implementations, the memory device further comprises: a pad-out structure on a second side of the semiconductor layer distant from the first semiconductor structure, and comprising a conductive pad coupled with the through interconnect structure; wherein the transistors are on a first side of the semiconductor layer close to the first semiconductor structure.

In some implementations, the second semiconductor structure further comprises: a second isolation structure in the semiconductor layer and surrounding the first isolation structures and the insulating structure.

In some implementations, a first depth of the first isolation structures is less than a second depth of the second isolation structure.

In some implementations, the semiconductor layer comprises a doped sublayer and an undoped sublayer; and the first isolation structures are embedded in the doped sublayer.

In some implementations, the through interconnect structure comprises: a first contact structure extending into a stack structure from a first side close to the first semiconductor structure; and a via contact extending through the semiconductor layer and extending into the stack structure from a second side opposite to the first side, and in contact with the first contact structure.

In some implementations, the stack structure comprises: a TiN layer; and a SiN layer.

In some implementations, the second semiconductor structure further comprises: a second contact structure extending through the SiN layer without extending through the TiN layer.

In some implementations, the pad-out structure further comprises: a third interconnect layer comprising third interconnect structures coupled between the conductive pad and the through interconnect structure.

In some implementations, the first semiconductor structure is a 3D NAND array comprising an array of vertical NAND memory strings.

In some implementations, the first semiconductor structure is a DRAM memory cells array comprising an array of vertical transistors and vertical capacitors.

Another aspect of the present disclosure provides a method of forming a memory device, comprising: forming a first semiconductor structure comprising an array of memory cells; forming a second semiconductor structure, comprising: forming transistors at a first side of a semiconductor layer, forming first isolation structures in the semiconductor layer and between the transistors, forming an insulating structure in the semiconductor layer and on a lateral side of the transistors, forming a second isolation structure in the semiconductor layer and surrounding the first isolation structures and the insulating structure; and forming a through interconnect structure extending through the insulating structure; and bonding the first semiconductor structure and the second semiconductor structure.

In some implementations, forming the first semiconductor structure further comprises forming a first interconnect layer comprising first interconnect structures coupled with the array of memory cells; and forming the second semiconductor structure further comprises forming a second interconnect layer comprising second interconnect structures coupled with the transistors and the through interconnect structure.

In some implementations, bonding the first semiconductor structure and the second semiconductor structure comprises: hybrid bonding the first semiconductor structure with the second semiconductor structure in a vertical direction, such that first interconnect structures are coupled with the second interconnect structures and the through interconnect structure.

In some implementations, the method further comprises: forming a pad-out structure on a second side of the semiconductor layer distant from the first semiconductor structure, and comprising a conductive pad coupled with the through interconnect structure, wherein the transistors are formed on a first side of the semiconductor layer close to the first semiconductor structure.

In some implementations, forming the second semiconductor structure further comprises: forming a stack structure; forming the through interconnect structure comprises forming a contact structure extending into the stack structure from a first side, and forming a via contact extending through the semiconductor layer and extending into the stack structure from a second side opposite to the first side, and in contact with the contact structure.

In some implementations, forming the stack structure comprises: forming a TiN layer; and forming a SiN layer.

In some implementations, forming the via contact comprises: thinning the substrate to expose the insulating structure; forming an opening extending through the insulating structure and extending into the stack structure from the second side to expose the contact structure; and forming the via contact in the opening.

In some implementations, forming the insulating structure comprises: forming a first insulating layer; forming a protecting layer surrounded by the first insulating layer; and forming a second insulating layer surrounded by the protecting layer; wherein the opening is formed to extend through the second insulating layer without damage the first insulating layer.

In some implementations, forming the through interconnect structure comprises: forming a contact structure on the first side of a semiconductor layer; forming a sacrificial layer laterally surrounded by the insulating structure; thinning the substrate to expose the insulating structure and the sacrificial layer; removing the sacrificial layer to form an opening that exposes the contact structure; and forming a via contact in the opening and in contact with the contact structure.

In some implementations, forming the second semiconductor structure further comprises: forming a second contact structure extending through the SiN layer without extending through the TiN layer.

In some implementations, forming the pad-out structure further comprises: forming a third interconnect layer comprising third interconnect structures coupled between the conductive pad and the through interconnect structure.

In some implementations, forming the first semiconductor structure comprises: forming a 3D NAND array comprising an array of vertical NAND memory strings.

In some implementations, forming the first semiconductor structure comprises: forming a DRAM memory cells array comprising an array of vertical transistors and vertical capacitors.

Other aspects of the present disclosure can be understood by those skilled in the art in light of the description, the claims, and the drawings of the present disclosure.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a schematic diagram of a cross-section of an exemplary 3D memory device, according to some aspects of the present disclosure.

FIG. 2A illustrates a schematic circuit diagram of an exemplary memory device, according to some aspects of the present disclosure.

FIG. 2B illustrates a schematic circuit diagram of an exemplary memory device, according to some aspects of the present disclosure.

FIG. 3 illustrates a schematic circuit diagram of an exemplary memory device, according to some aspects of the present disclosure.

FIG. 4A illustrates a schematic structural diagram of an exemplary 3D memory device in a cross-sectional side view, according to various implementations of the present disclosure.

FIG. 4B illustrates a schematic structural diagram of an exemplary 3D memory device in a planar view, according to various implementations of the present disclosure.

FIG. 5A illustrates a schematic structural diagram of an exemplary 3D memory device in a cross-sectional side view, according to various implementations of the present disclosure.

FIG. 5B illustrates a schematic structural diagram of an exemplary 3D memory device in a planar view, according to various implementations of the present disclosure.

FIG. 6 illustrates a block diagram of an exemplary system having a 3D memory device, according to some aspects of the present disclosure.

FIG. 7A illustrates a diagram of a memory card having a 3D memory device, according to some aspects of the present disclosure.

FIG. 7B illustrates a diagram of a solid-state drive (SSD) having a 3D memory device, according to some aspects of the present disclosure.

FIG. 8 illustrates a flow diagram of an exemplary method for forming a 3D memory device, according to some aspects of the present disclosure.

FIGS. 9A-9F illustrate schematic cross-sectional views of an exemplary 3D memory device at certain fabricating stages of the method shown in FIG. 8, according to some aspects of the present disclosure.

FIG. 10 illustrates a flow diagram of an exemplary method for forming a 3D memory device, according to some aspects of the present disclosure.

FIGS. 11A-11F illustrate schematic cross-sectional views of an exemplary 3D memory device at certain fabricating stages of the method shown in FIG. 10, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

As semiconductor technology advances, three-dimensional (3D) memory devices, such as 3D NAND memory devices and 3D DRAM devices, keep increasing the memory density of the memory cell array. With the increase in the number of memory cells of the 3D architecture, the CMOS peripheral circuit needs more complex and size scaling. For example, a complementary metal-oxide-semiconductor wafer (“CMOS wafer” hereinafter) is bonded with a memory cell array wafer (“array wafer” hereinafter) to form a framework of the 3D memory device. Specifically, the disclosed 3D memory device can be a part of a non-monolithic 3D memory device, in which components (e.g., portions of the CMOS devices and the memory cell array device) are formed separately on different wafers and then bonded in a face-to-face manner.

As the dimensions of memory cell arrays continue to shrink, compressing the areas of CMOS devices becomes increasingly critical. While device scaling is pursued to achieve higher memory density efficiency, significant bottlenecks have emerged. The array side pad-out arrangement increases the distance for power delivery to the routing circuits, posing challenges to meet rising speed demands. These factors add complexity to maintaining memory device performance as size is reduced, with power routing paths becoming longer and more difficult to optimize for high-speed operations.

To address these issues, the disclosed memory devices and fabrication methods involve placing the pad-out layer on the backside of the CMOS wafer and incorporating through-stack contact structures to significantly shorten the power delivery path. This reduces metal routing delays and enhances overall chip performance. Additionally, integrating peripheral and decoder circuits beneath the memory array enables better layout optimization, resulting in a substantial reduction in CMOS area (e.g., 20%-30%) and improved cell efficiency. These innovations not only boost chip performance but also reduce process complexity. By utilizing backside power delivery, power transmission efficiency is improved, mitigating bottlenecks caused by long power paths and increasing overall speed.

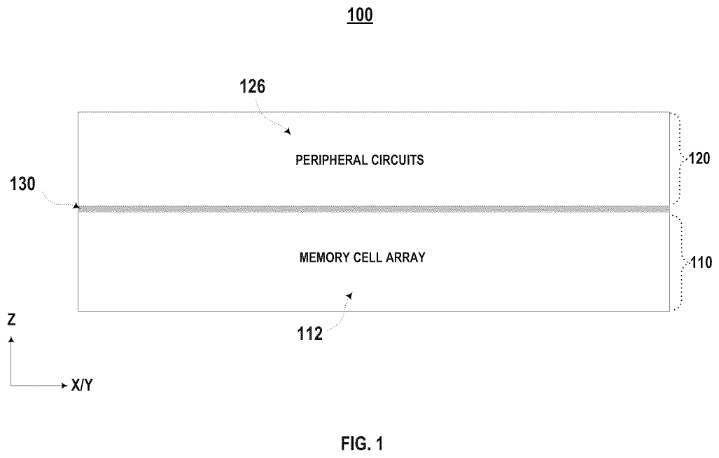

FIG. 1 illustrates a schematic view of a cross-section of a 3D memory device 100, according to some aspects of the present disclosure. In some implementations, 3D memory device 100 represents an example of a bonded chip. In some implementations, at least some of the components of 3D memory device 100 (e.g., first wafer/first semiconductor structure/array wafer 110 and second wafer/second semiconductor structure/CMOS wafer 120 as shown in FIG. 1) are formed separately on different substrates in parallel and then jointed to form a bonded chip (a process referred to herein as a “parallel process”). In some other implementations not shown, the 3D memory device can be a single wafer structure, in which the memory array and CMOS can be sequentially formed on a single substrate.

It is noted that X/Y and Z axes are added in FIG. 1 to further illustrate the spatial relationships of the components of a memory device. A substrate of a memory device, e.g., 3D memory device 100, includes two lateral surfaces (e.g., a top surface and a bottom surface) extending laterally in the X and Y directions (e.g., word line direction and bit line direction). As used herein, whether one component (e.g., a layer or a device) is “on,” “above,” or “below” another component (e.g., a layer or a device) of a memory device is determined relative to the substrate of the memory device in the Z direction (the vertical direction or thickness direction) when the substrate is positioned in the lowest plane of the memory device in the Z direction. The same notion for describing the spatial relationships is applied throughout the present disclosure.

3D memory device 100 can include a first semiconductor structure 110 including an array of memory cells (also referred to herein as a “memory cell array 112”). In some implementations, the memory cell array 112 includes an array of NAND Flash memory cells. For ease of description, a NAND Flash memory cell array may be used as an example for describing the memory cell array 112 in the present disclosure. In some implementations, the memory cell array 112 includes an array of DRAM cells. But it is understood that the memory cell array 112 is not limited to NAND Flash memory cell array or DRAM cell array, and may include any other suitable types of memory cell arrays, such as NOR Flash memory cell array, phase change memory (PCM) cell array, ferroelectric DRAM (FRAM) cell array, resistive memory cell array, magnetic memory cell array, spin transfer torque (STT) memory cell array, to name a few.

First semiconductor structure 110 can include a memory device in which the memory cells are provided in the form of an array of 3D memory cells. In some implementations, when the memory cell array 112 is a NAND memory cell array, the NAND memory cells can be organized as an array of 3D NAND memory strings, each of which extends vertically above the substrate (in 3D) through a stack structure, e.g., a memory stack. Depending on the 3D NAND technology (e.g., the number of layers/tiers in the memory stack), a 3D NAND memory string typically includes a certain number of NAND memory cells, each of which includes a floating-gate transistor or a charge-trap transistor. The 3D NAND memory string can be organized into pages or fingers, which are then organized into blocks in which each NAND memory cell is coupled to a separate line called a bit line (BL). All cells with the same vertical position in the NAND memory cell can be coupled through the control gates by a word line (WL). In some implementations, a memory plane contains a certain number of blocks that are coupled through the same bit line. First semiconductor structure 110 can include one or more memory planes.

In some other implementations, when the memory cell array 112 is a DRAM cell array, each DRAM cell can include a vertical transistor, and a storage unit coupled to the vertical transistor. The vertical transistors can be vertical metal-oxide-semiconductor field-effect transistors (MOSFETs), and the storage units can be capacitors for storing charges as the binary information stored by the respective DRAM cells. In some other implementations, when the memory cell array 112 is a PCM cell array, the storage unit can be a PCM element (e.g., including chalcogenide alloys) for storing binary information of the respective PCM cell based on the different resistivities of the PCM element in the amorphous phase and the crystalline phase. In some other implementations, when the memory cell array 112 is a FRAM cell array, the storage unit can be a ferroelectric capacitor for storing binary information of the respective FRAM cell based on the switch between two polarization states of ferroelectric materials under an external electric field.

As shown in FIG. 1, 3D memory device 100 can also include one or more peripheral circuits 126 of the memory cell array form in a second semiconductor structure 120 to perform all the read/program (write)/erase operations. The one or more peripheral circuits 126 (a.k.a. control and sensing circuits) can include any suitable digital, analog, and/or mixed-signal circuits used for facilitating the operations of the memory cell array. For example, the one or more peripheral circuits 126 can include one or more of a page buffer, a decoder (e.g., a row decoder and a column decoder), a sense amplifier, a driver (e.g., a word line driver), an I/O circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The one or more peripheral circuits 126 in second semiconductor structure 120 can use CMOS technology, e.g., which can be implemented with logic processes in any suitable technology nodes. In some implementations, the second semiconductor structure 120 does not include any memory cell. In other words, the second semiconductor structure 120 only includes peripheral circuits 126, but not the memory cell array 112, according to some implementations. As a result, memory cell array 112 can be only included in the first semiconductor structure 110, but not in second semiconductor structure 120.

As shown in FIG. 1, the first semiconductor structure 110 and second semiconductor structure 120 are stacked in two different planes, according to some implementations. In some implementations, memory cell array 112 can be arranged in first semiconductor structure 110, peripheral circuits 126 can be arranged in second semiconductor structure 120, and can be stacked over first semiconductor structure 110 to reduce the planar size of 3D memory device 100, compared with memory devices in which all the peripheral circuits are disposed in a same plane.

As shown in FIG. 1, 3D memory device 100 further includes a bonding interface 130 vertically between first semiconductor structure 110 and second semiconductor structure 120. Bonding interface 130 can be an interface between two semiconductor structures formed by any suitable bonding technologies as described below in detail, such as hybrid bonding, anodic bonding, fusion bonding, transfer bonding, adhesive bonding, and eutectic bonding, to name a few. In some implementations, as shown in FIG. 1, the second semiconductor structure 120 is bonded to first semiconductor structure 110 on opposite sides thereof.

As described below in detail, first semiconductor structure 110 and second semiconductor structure 120 can be fabricated separately (and in parallel in some implementations) by the parallel process, such that the thermal budget of fabricating one of first and second semiconductor structures 110 and 120 does not limit the processes of fabricating another one of first and second semiconductor structures 110 and 120. Moreover, a large number of interconnects (e.g., bonding contacts and/or inter-layer vias (ILVs)/through substrate vias (TSVs)) can be formed across bonding interface 130 to make direct, short-distance (e.g., micron- or submicron-level) electrical connections between first and second semiconductor structures 110 and 120, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer among memory cell array 112 and peripheral circuits 126 in first and second semiconductor structures 110 and 120 can be performed through the interconnects (e.g., bonding contacts and/or ILVs/TSVs) across bonding interface 130. By vertically integrating first and second semiconductor structures 110 and 120, the chip size can be reduced, and the memory cell density can be increased.

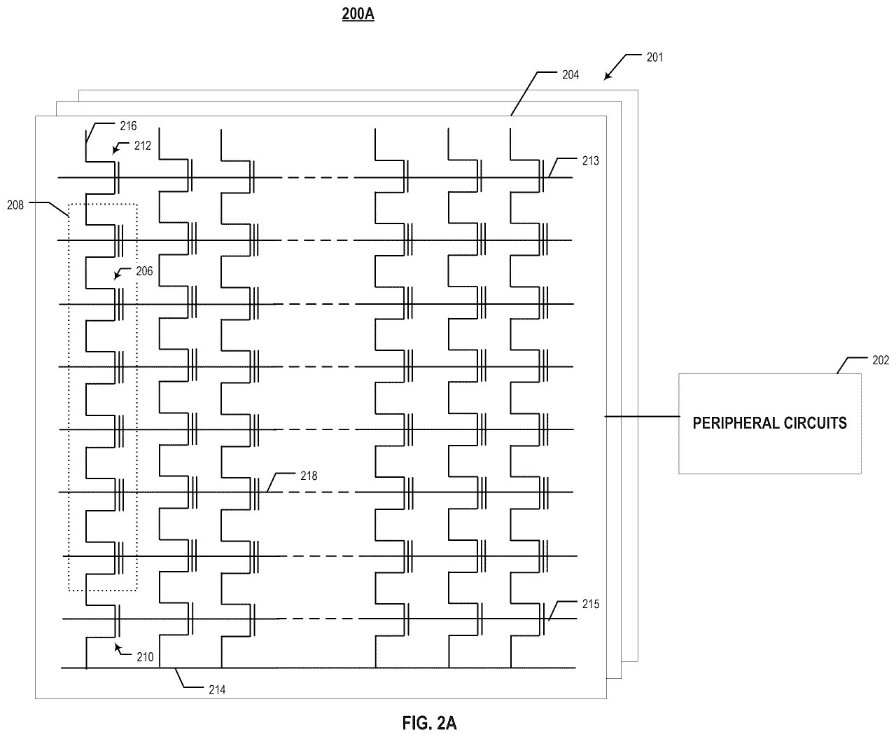

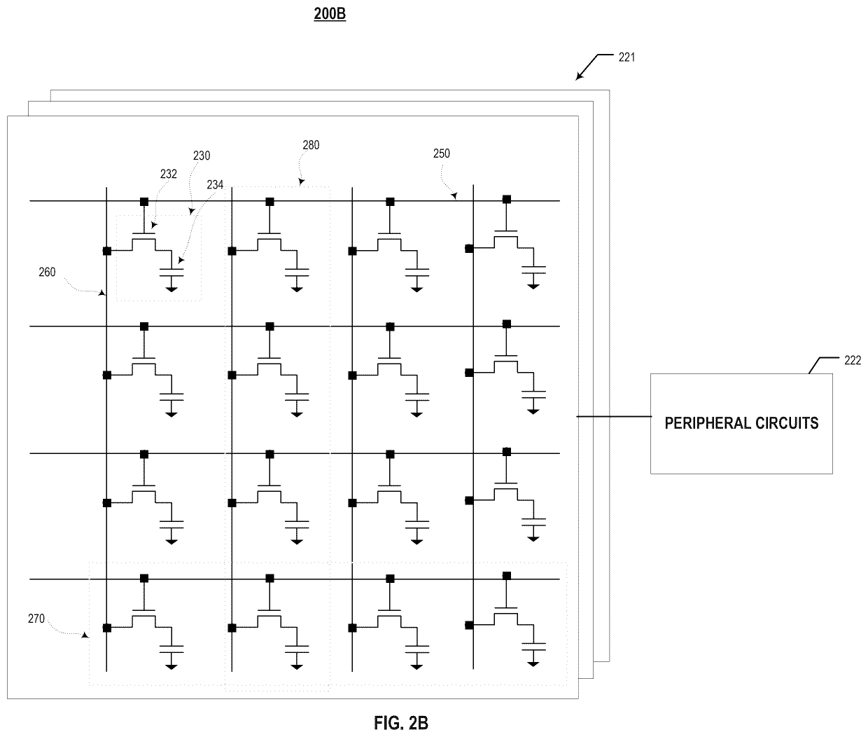

FIG. 2A illustrates a schematic circuit diagram of a memory device 200A including peripheral circuits, according to some aspects of the present disclosure. Memory device 200A can include one or more NAND memory cell arrays 201 and peripheral circuits 202 coupled to the one or more NAND memory cell arrays 201. In each NAND memory cell array 201, the memory cells 206 are provided in the form of an array of NAND memory strings 208 each extending vertically above a substrate (not shown). In some implementations, each NAND memory string 208 includes a plurality of memory cells 206 coupled in series and stacked vertically. Each memory cell 206 can hold a continuous, analog value, such as an electrical voltage or charge, that depends on the number of electrons trapped within a region of memory cell 206. Each memory cell 206 can be either a floating gate type of memory cell including a floating-gate transistor or a charge trap type of memory cell including a charge-trap transistor.

In some implementations, each memory cell 206 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 206 is a multi-level cell (MLC) that is capable of storing more than a single bit of data in more than four memory states. For example, the MLC can store two bits per cell, three bits per cell (also known as triple-level cell (TLC)), or four bits per cell (also known as a quad-level cell (QLC)). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state.

As shown in FIG. 2A, each NAND memory string 208 can include a source select gate (SSG) transistor 210 at its source end and a drain select gate (DSG) transistor 212 at its drain end. SSG transistor 210 and DSG transistor 212 can be configured to activate selected NAND memory strings 208 (columns of the array) during read and program operations. In some implementations, SSG transistors 210 of NAND memory strings 208 in the same block 204 are coupled through a same source line (SL) 214, e.g., a common SL, for example, to the ground. DSG transistor 212 of each NAND memory string 208 is coupled to a respective bit line 216 from which data can be read or programmed via an output bus (not shown), according to some implementations. In some implementations, each NAND memory string 208 is configured to be selected or deselected by applying a select voltage (e.g., above the threshold voltage of DSG transistor 212) or a deselect voltage (e.g., 0 V) to respective DSG transistor 212 through one or more DSG lines 213 and/or by applying a select voltage (e.g., above the threshold voltage of SSG transistor 210) or a deselect voltage (e.g., 0 V) to respective SSG transistor 210 through one or more SSG lines 215.

As shown in FIG. 2A, NAND memory strings 208 can be organized into multiple blocks 204, each of which can have a common source line 214. In some implementations, each block 204 is the basic data unit for erase operations, i.e., all memory cells 206 on the same block 204 are erased at the same time. Memory cells 206 of adjacent NAND memory strings 208 can be coupled through word lines 218 that select which row of memory cells 206 is affected by read and program operations. Each word line 218 can include a plurality of control gates (gate electrodes) at each memory cell 206 and a gate line coupling the control gates.

FIG. 2B illustrates a schematic circuit diagram of a memory device 200B including peripheral circuits, according to some aspects of the present disclosure. Memory device 200B can include one or more DRAM cell arrays 221 and peripheral circuits 222 coupled to the one or more DRAM cell arrays 221. In some implementations, the DRAM cells 230 can be arranged in a two-dimensional (2D) array having rows and columns.

In some implementations, the memory device 200B can include word lines 250 coupling the DRAM cell array 221 to the peripheral circuits 222 for controlling the switch of vertical transistors 232 in DRAM cells 230 located in a row, as well as bit lines 260 coupling the DRAM cell array 221 to the peripheral circuits 222 for sending data to and/or receiving data from the capacitors 234 in DRAM cells 230 located in a column. That is, each word line 250 is coupled to a respective row of DRAM cells 230, and each bit line 260 is coupled to a respective column of DRAM cells 230. In some implementations, the gate of vertical transistor 232 is coupled to word line 250, one of the source and the drain of vertical transistor 232 is coupled to bit line 260, the other one of the source and the drain of vertical transistor 232 is coupled to one electrode of capacitor 234, and the other electrode of capacitor 234 is coupled to the ground.

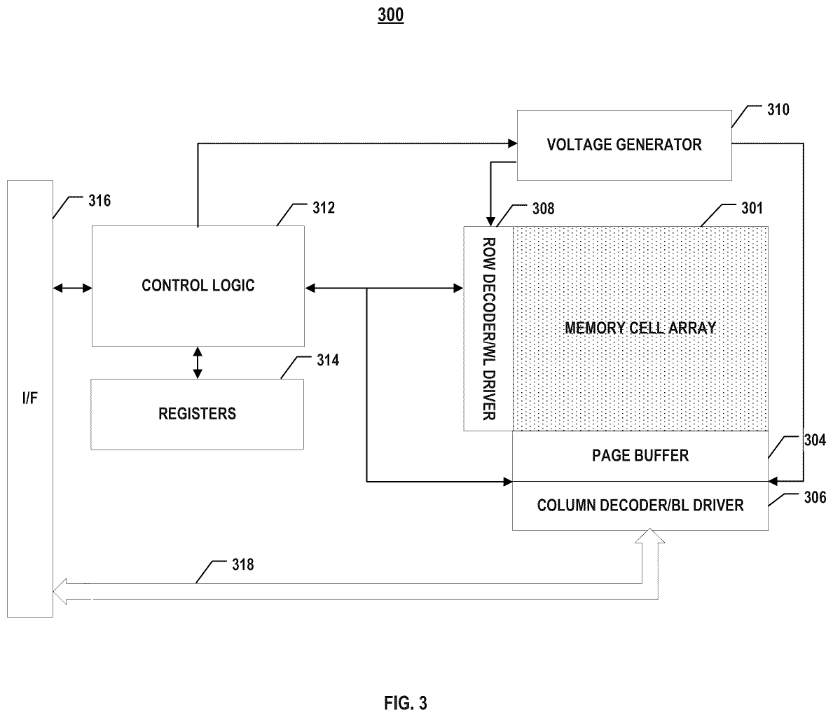

Referring to FIG. 2A, the peripheral circuits 202 can be coupled to NAND memory cell array 201 through bit lines 216, word lines 218, source lines 214, SSG lines 215, and DSG lines 213. Referring to FIG. 2B, the peripheral circuits 222 can be coupled to DRAM cell array 221 through bit lines 260 and word lines 250. As described above, the peripheral circuits 202/222 can include any suitable circuits for facilitating the operations of memory cell array 201/221 by applying and sensing voltage signals and/or current signals through various lines to and from each target memory cell 206/230. The peripheral circuits 202/222 can include various types of peripheral circuits formed using CMOS technologies. For example, FIG. 3 illustrates a memory device 300 comprising a memory cell array 301 and peripheral circuits. The peripheral circuits can be peripheral circuits 202/222 shown in FIGS. 2A and 2B, and can include a page buffer 304, a column decoder/bit line driver 306, a row decoder/word line driver 308, a voltage generator 310, control logic 312, registers 314, an interface (I/F) 316, and a data bus 318. It is understood that in some examples, additional peripheral circuits 202/222 may be included as well.

In some implementations, the page buffer 304 can be configured to buffer data read from or programmed to memory cell array 201/221 according to the control signals of control logic 312. In one example, page buffer 304 may store one page of program data (write data) to be programmed into NAND memory cell array 201 or one page 270 of DRAM cell array 221. In another example, page buffer 304 also performs program verify operations to ensure that the data has been properly programmed into memory cells 206 or DRAM cells 230 coupled to selected word lines 218/250.

Row decoder/word line driver 308 can be configured to be controlled by control logic 312 and select block 204/224 of memory cell array 201/221 and a word line 218/250 of selected block 204/224. Row decoder/word line driver 308 can be further configured to drive memory cell array 201/221. For example, row decoder/word line driver 308 may drive memory cells 206/230 coupled to the selected word line 218/250 using a word line voltage generated from voltage generator 310.

Column decoder/bit line driver 306 can be configured to be controlled by control logic 312 and select one or more 3D NAND memory strings 208 or columns 280 of DRAM cells 230 by applying bit line voltages generated from voltage generator 310. For example, column decoder/bit line driver 306 may apply column signals for selecting a set of N bits of data from page buffer 304 to be output in a read operation.

Control logic 312 can be coupled to each peripheral circuit 202/222 and configured to control operations of peripheral circuits 202/222. Registers 314 can be coupled to control logic 312 and include status registers, command registers, and address registers for storing status information, command operation codes (OP codes), and command addresses for controlling the operations of each peripheral circuit 202/222.

Interface 316 can be coupled to control logic 312 and configured to interface memory cell array 201/221 with a memory controller (not shown). In some implementations, interface 316 acts as a control buffer to buffer and relay control commands received from the memory controller and/or a host (not shown) to control logic 312 and status information received from control logic 312 to the memory controller and/or the host. Interface 316 can also be coupled to page buffer 304 and column decoder/bit line driver 306 via data bus 318 and act as an I/O interface and a data buffer to buffer and relay the program data received from the memory controller and/or the host to page buffer 304 and the read data from page buffer 304 to the memory controller and/or the host. In some implementations, interface 316 and data bus 318 are parts of an I/O circuit of peripheral circuits 202/222.

Voltage generator 310 can be configured to be controlled by control logic 312 and generate the word line voltages (e.g., read voltage, program voltage, pass voltage, local voltage, and verification voltage) and the bit line voltages to be supplied to memory cell array 201/221. In some implementations, voltage generator 310 is part of a voltage source that provides voltages at various levels of different peripheral circuits 202/222. Consistent with the scope of the present disclosure, in some implementations, the voltages provided by voltage generator 310, for example, to row decoder/word line driver 308, column decoder/bit line driver 306, and page buffer 304 are above certain levels that are sufficient to perform the memory operations.

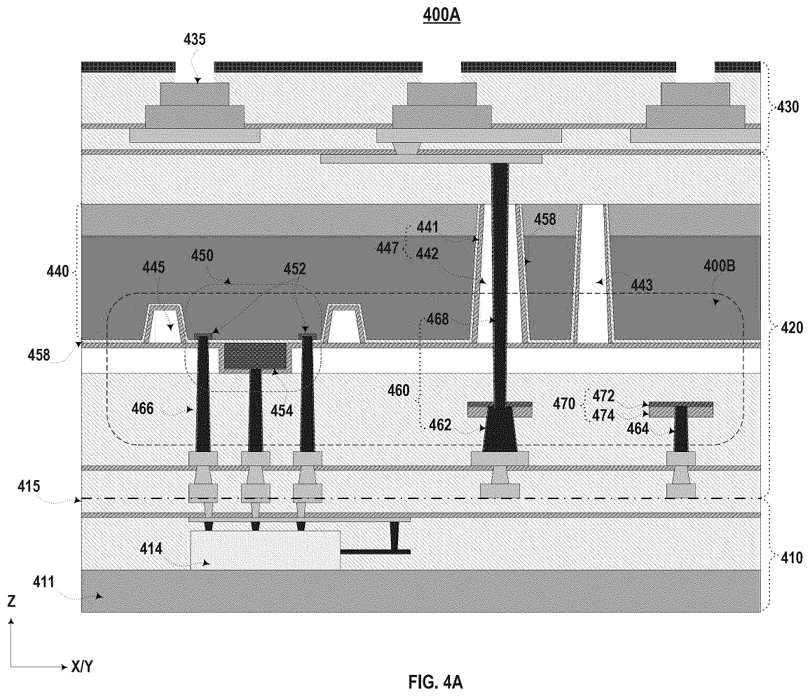

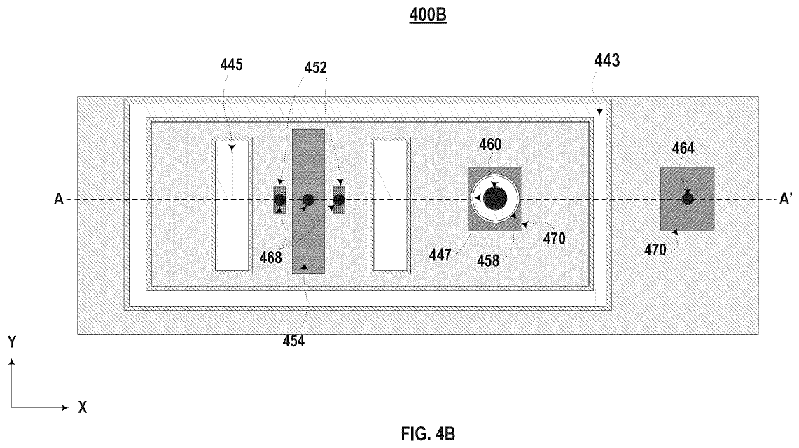

FIGS. 4A and 4B illustrate schematic structural diagrams of an exemplary 3D memory device, according to some implementations of the present disclosure. FIG. 4B illustrates a schematic structural diagram of a portion 400B of the exemplary 3D memory device 400A shown in FIG. 4A in a planar view, according to various implementations of the present disclosure. FIG. 4B illustrates a schematic structural diagram of the exemplary 3D memory device 400A in a cross-sectional view along the AA′ line shown in FIG. 4B, according to various implementations of the present disclosure. It is noted that X, Y, and Z axes are included in FIGS. 4A and 4B to further illustrate the spatial relationship of the components in 3D memory devices.

As shown in FIG. 4A, in some implementations, 3D memory device 400A is a bonded chip including a first semiconductor structure 410 and a second semiconductor structure 420 stacked over first semiconductor structure 410. The first semiconductor structure 410 and the second semiconductor structure 420 are jointed at a bonding interface 415 therebetween, according to some implementations.

As shown in FIG. 4A, first semiconductor structure 410 can include semiconductor layer 411, which can include silicon (e.g., single crystalline silicon, c-Si, or poly crystalline silicon, etc.), silicon germanium (SiGe), gallium arsenide (GaAs), germanium (Ge), silicon-on-insulator (SOI), or any other suitable materials. In some implementations, the first semiconductor structure 410 of 3D memory device 400A further includes a memory cell array 414. The memory cell array 414 can be any suitable type of memory cell array, such as NAND Flash memory cell array, DRAM cell array, NOR Flash memory cell array, PCM cell array, FRAM cell array, resistive memory cell array, magnetic memory cell array, STT memory cell array, etc.

In some implementations, the first semiconductor structure 410 of 3D memory device 400A further includes an interconnect layer above the memory cell array 414 to transfer electrical signals from/to the memory cell array 414. The interconnect layer can include a plurality of interconnects (also referred to herein as contacts), including lateral interconnect lines and vertical interconnect access (VIA) contacts. As used herein, the term interconnects can broadly include any suitable types of interconnects, such as middle-end-of-line (MEOL) interconnects and back-end-of-line (BEOL) interconnects. The interconnect layer can further include one or more interlayer dielectric (ILD) layers (a.k.a. intermetal dielectric (IMD) layers) in which the interconnect lines and VIA contacts can form. That is, the interconnect layer can include interconnect lines and VIA contacts in multiple ILD layers. The interconnect lines and VIA contacts in the interconnect layer can include conductive materials including, but not limited to, W, Co, Cu, or Al, silicides, or any combination thereof. The ILD layers in the interconnect layer can include dielectric materials including, but not limited to, silicon oxide, silicon nitride, silicon oxynitride, low dielectric constant (low-k) dielectrics, or any combination thereof.

In some implementations, the first semiconductor structure 410 of 3D memory device 400A can further include a bonding layer at bonding interface 415 and above the interconnect layer. Bonding layer can include a plurality of bonding contacts and dielectrics electrically isolating bonding contacts. Bonding contacts can include conductive materials including, but not limited to, W, Co, Cu, Al, silicides, or any combination thereof. The remaining area of bonding layer can be formed with dielectrics including, but not limited to, silicon oxide, silicon nitride, silicon oxynitride, low-k dielectrics, or any combination thereof. The bonding contacts and surrounding dielectrics in bonding layer can be used for hybrid bonding.

As shown in FIG. 4A, the second semiconductor structure 420 of 3D memory device 400A can include a semiconductor layer 440, which can include Si, SiGe, GaA, Ge, or any other suitable semiconductor materials. In some implementations, the semiconductor layer 440 can be monocrystal silicon layer. The second semiconductor structure 420 of 3D memory device 400A can include one or more peripheral circuits on semiconductor layer 440. In some implementations, the one or more peripheral circuits can include any suitable peripheral circuits 202/222 discussed above. In some implementations, the one or more peripheral circuits can include a plurality of transistors 450 formed at a first side of the semiconductor layer 440. In some implementations, doped regions (e.g., source/drain regions 452 of the transistors 450) can be formed in the semiconductor layer 440. In some implementations, the gate structure 454 of the transistor 450 is located on a first side of semiconductor layer 440. In some implementations, the transistors 450 are surrounded by an enclosed isolation structure 443 (e.g., deep trench isolation (DTI)) in the semiconductor layer 440, as shown in FIG. 4B.

In some implementations, the second semiconductor structure 420 of 3D memory device 400A can further include shallow isolation structures (STIs) 445 in the semiconductor layer 440 and between the transistors 450, and further include one or more insulating structures 447 extending through the semiconductor layer 440 and on a lateral side of the transistors 450. In some implementations, the insulating structure 447 can be either located within or outside of the enclosed isolation structure 443. In some implementations, the insulating structures 447 can include a dielectric filling material 442 laterally surrounded by an insulating layer 458, such as a silicon oxide layer. In some implementations, a protection layer 441, such as a silicon nitride layer or any other suitable layer having a different material from the insulating layer 458, can be optionally formed between the insulating layer 458 and the dielectric filling material 442. In some implementations, the height of the STIs 445 in a vertical direction (i.e., the Z direction) is less than the height of the insulating structure 447 or the enclosed isolation structure 443. In some implementations, the top surfaces of the STIs 445 and the insulating structure 447 are coplanar. In some implementations, the enclosed isolation structure 443 and the insulating structure 447 extend through the semiconductor layer 440.

In some implementations, the second semiconductor structure 420 of 3D memory device 400A can further include an interconnect layer on the plurality of transistors 450 to transfer electrical signals. The interconnect layer can include a plurality of contact structures 462, 464, 466 on the first side of the semiconductor layer 440. The contact structures 462, 464, 466 can be formed by any suitable MEOL method, disposed at the same side of semiconductor layer 411 with the transistors 450 and thus, viewed as front-side contact structures. The transistor contact structures 466 can include source/drain contacts in contact with the source/drain regions 452, and gate contacts in contact with gate structures 454 of the transistors 450.

In some implementations, the first contact structure 462 and the second contact structure 464 can extend into a first side of a stack structure 470. In some implementations, the stack structure 470 can include a TiN layer 472 and a SiN layer 474. The first contact structure 462 and the second contact structure 464 can extend through the SiN layer 474 without extending through the TiN layer 472. In some implementations, a lateral dimension of a first end of the first contact structure 462 in contact with the stack structure is less than a lateral dimension of a second end of the first contact structure 462 distant from the stack structure 470. In some implementations, the first contact structure 462 can be in contact with a via contact 468 extending through the semiconductor layer 440 by extending through the insulating structure 447 and extending into a second side of the stack structure 470. As shown in FIG. 4A, the first contact structure 462 and the via contact 468 can constitute a through interconnect structure 460.

In some implementations, the interconnect structures in the interconnect layer can include any suitable types of contacts and/or pads, such as lateral interconnect lines and VIA contacts, embedded in one or more ILD layers. The interconnect lines and VIA contacts in the interconnect layer can include conductive materials including, but not limited to, W, Co, Cu, or Al, silicides, or any combination thereof. The ILD layers in the interconnect layer can include dielectric materials including, but not limited to, silicon oxide, silicon nitride, silicon oxynitride, low-k dielectrics, or any combination thereof. In some implementations, the interconnect structures in the interconnect layer can further include a silicide layer surrounded by an adhesive layer (e.g., titanium nitride (TiN)), etc. In some implementations, the interconnect structures in the interconnect layer may further include a spacer (e.g., a dielectric layer) to electrically separate the conductive materials.

Similar to the first semiconductor structure 410, the second semiconductor structure 420 of 3D memory device 400A can also include a bonding layer at bonding interface 415. Bonding layer can include a plurality of bonding contacts and dielectrics electrically isolating bonding contacts. Bonding contacts can include conductive materials including, but not limited to, W, Co, Cu, Al, silicides, or any combination thereof. The remaining area of bonding layer can be formed with dielectrics including, but not limited to, silicon oxide, silicon nitride, silicon oxynitride, low-k dielectrics, or any combination thereof. Bonding contacts and surrounding dielectrics in bonding layer can be used for hybrid bonding. Bonding contacts of the first semiconductor structure 410 are in contact with bonding contacts of the second semiconductor structure 420 at bonding interface 415, according to some implementations.

As shown in FIG. 4A, the second semiconductor structure 420 can be bonded on top of the first semiconductor structure 410 in a face-to-face manner at bonding interface 415. In some implementations, bonding interface 415 is a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, bonding interface 415 is the place at which the bonding layer of the first semiconductor structure 410 and the bonding layer of the second semiconductor structure 420 are met and bonded. The bonding contacts of the bonding layers of the first and second semiconductor structures 410 and 420 can be in electrical contact with each other, such that the one or more peripheral circuits in the second semiconductor structure 420 can be coupled with the memory cell array 414 in the first semiconductor structure 410.

As shown in FIG. 4A, in some implementations, the 3D memory device 400A can further include a pad-out structure 430 on the back side of the semiconductor layer 440. The pad-out structure 430 can include one or more conductive pads 435 and an interconnect layer comprising interconnect structures coupled between the conductive pads 435 and the via contact 468 to transfer electrical signals. The interconnect layer of the pad-out structure 430 can include a plurality of interconnects, including lateral interconnect lines and VIA contacts, formed by any suitable BEOL method. The interconnect layer of the pad-out structure 430 can further include one or more ILD layers in which the interconnect lines and VIA contacts can form. The interconnect lines and VIA contacts in the interconnect layer can include conductive materials including, but not limited to, W, Co, Cu, or Al, silicides, or any combination thereof. The ILD layers in the interconnect layer can include dielectric materials including, but not limited to, silicon oxide, silicon nitride, silicon oxynitride, low-k dielectrics, or any combination thereof.

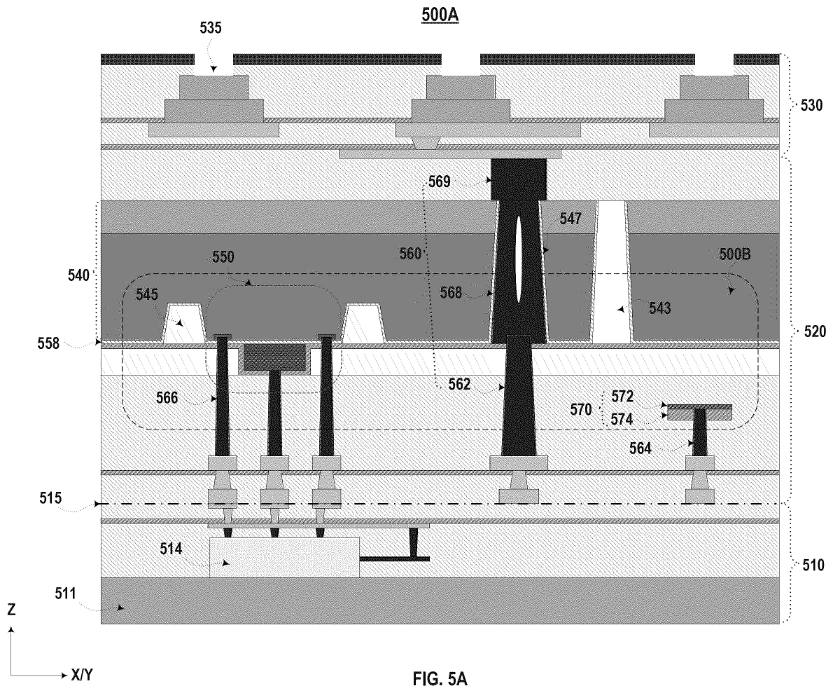

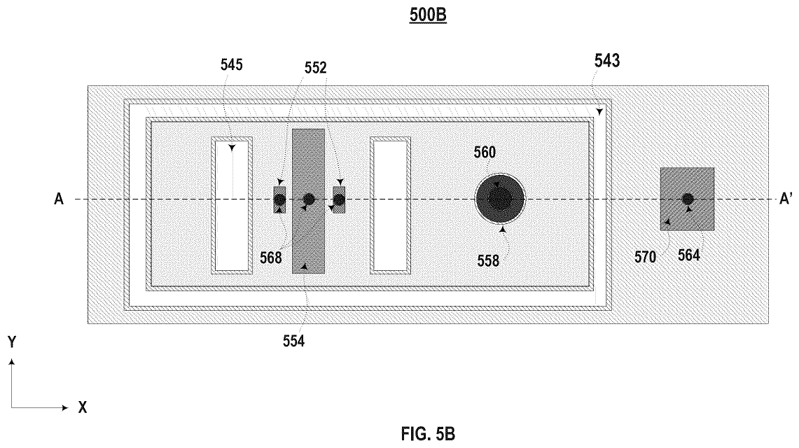

FIGS. 5A and 5B illustrate schematic structural diagrams of an exemplary 3D memory device, according to some other implementations of the present disclosure. FIG. 5B illustrates a schematic structural diagram of a portion 500B of the exemplary 3D memory device 500A shown in FIG. 5A in a planar view, according to various implementations of the present disclosure. FIG. 5B illustrates a schematic structural diagram of the exemplary 3D memory device 500A in a cross-sectional view along the AA′ line shown in FIG. 5B, according to various implementations of the present disclosure. It is noted that X, Y, and Z axes are included in FIGS. 5A and 5B to further illustrate the spatial relationship of the components in 3D memory devices.

As shown in FIG. 5A, in some implementations, 3D memory device 500A is a bonded chip including a first semiconductor structure 510 and a second semiconductor structure 520 stacked over first semiconductor structure 510. The first semiconductor structure 510 and the second semiconductor structure 520 are jointed at a bonding interface 515 therebetween, according to some implementations.

As shown in FIG. 5A, first semiconductor structure 510 can include semiconductor layer 511, which can include silicon (e.g., single crystalline silicon, c-Si, or poly crystalline silicon, etc.), SiGe, GaAs, Ge, SO), or any other suitable materials. In some implementations, first semiconductor structure 510 of 3D memory device 500A further includes a memory cell array 514. The memory cell array 514 can be any suitable type of memory cell array, such as NAND Flash memory cell array, DRAM cell array, NOR Flash memory cell array, PCM cell array, FRAM cell array, resistive memory cell array, magnetic memory cell array, STT memory cell array, etc.

In some implementations, the first semiconductor structure 510 of 3D memory device 500A further includes an interconnect layer above the memory cell array 514 to transfer electrical signals from/to the memory cell array 514. The interconnect layer can include a plurality of interconnects, including lateral interconnect lines and via contacts. The interconnect layer can further include one or more ILD layers in which the interconnect lines and via contacts can form. That is, the interconnect layer can include interconnect lines and via contacts in multiple ILD layers. The interconnect lines and VIA contacts in the interconnect layer can include conductive materials including, but not limited to, W, Co, Cu, or Al, silicides, or any combination thereof. The ILD layers in the interconnect layer can include dielectric materials including, but not limited to, silicon oxide, silicon nitride, silicon oxynitride, low-k dielectrics, or any combination thereof.

In some implementations, the first semiconductor structure 510 of 3D memory device 500A can further include a bonding layer at bonding interface 515 and above the interconnect layer. Bonding layer can include a plurality of bonding contacts and dielectrics electrically isolating bonding contacts. Bonding contacts can include conductive materials including, but not limited to, W, Co, Cu, Al, silicides, or any combination thereof. The remaining area of bonding layer can be formed with dielectrics including, but not limited to, silicon oxide, silicon nitride, silicon oxynitride, low-k dielectrics, or any combination thereof. The bonding contacts and surrounding dielectrics in bonding layer can be used for hybrid bonding.

As shown in FIG. 5A, the second semiconductor structure 520 of 3D memory device 500A can include a semiconductor layer 540, which can include Si, SiGe, GaA, Ge, or any other suitable semiconductor materials. In some implementations, the semiconductor layer 540 can be monocrystal silicon layer. The second semiconductor structure 520 of 3D memory device 500A can include one or more peripheral circuits on semiconductor layer 540. In some implementations, the one or more peripheral circuits can include any suitable peripheral circuits 202/222 discussed above. In some implementations, the one or more peripheral circuits can include a plurality of transistors 550 formed at a first side of the semiconductor layer 540. In some implementations, doped regions (e.g., source/drain regions 552 of the transistors 550) can be formed in the semiconductor layer 540. In some implementations, the gate structure 554 of the transistor 550 is located on a first side of semiconductor layer 540. In some implementations, the transistors 550 are surrounded by an enclosed isolation structure 543 (e.g., deep trench isolation (DTI)) in the semiconductor layer 540, as shown in FIG. 5B.

In some implementations, the second semiconductor structure 520 of 3D memory device 500A can further include shallow isolation structures (STIs) 545 in the semiconductor layer 540 and between the transistors 550, and further include one or more insulating structures 547 extending through the semiconductor layer 540 and on a lateral side of the transistors 550. In some implementations, the insulating structure 547 can be part of the insulating layer 558 (e.g., a silicon oxide layer) that extends through the semiconductor layer 540, can be either located within or outside of the enclosed isolation structure 543. In some implementations, the height of the STIs 545 in a vertical direction (i.e., the Z direction) is less than the height of the insulating structure 547 or the enclosed isolation structure 543. In some implementations, the top surfaces of the STIs 545 and the insulating structure 547 are coplanar. In some implementations, the enclosed isolation structure 543 and the insulating structure 547 extend through the semiconductor layer 540.

In some implementations, the second semiconductor structure 520 of 3D memory device 500A can further include an interconnect layer on the plurality of transistors 550 to transfer electrical signals. The interconnect layer can include a plurality of contact structures 562, 564, 566 on the first side of the semiconductor layer 540. The contact structures 562, 564, 566 can be formed by any suitable MEOL method, disposed at the same side of semiconductor layer 511 with the transistors 550 and thus, viewed as front-side contact structures. The transistor contact structures 566 can include source/drain contacts in contact with the source/drain regions 552, and gate contacts in contact with gate structures 554 of the transistors 550.

In some implementations, the second contact structure 564 can extend into a first side of a stack structure 570. In some implementations, the stack structure 570 can include a TiN layer 572 and a SiN layer 574. The first contact structure 562 and the second contact structure 564 can extend through the SiN layer 574 without extending through the TiN layer 572. In some implementations, a lateral dimension of a first end of the second contact structure 564 in contact with the stack structure is less than a lateral dimension of a second end of the second contact structure 564 distant from the stack structure 570. In some implementations, the first contact structure 562 can be in contact with a via contact 568 extending through the semiconductor layer 540 by extending through the insulating structure 547, and the via contact 568 is in contact with a third contact structure 569. As shown in FIG. 4A, the first contact structure 562, the via contact 568, and the third contact structure 569 can constitute a through interconnect structure 560.

In some implementations, the interconnect structures in the interconnect layer can include any suitable types of contacts and/or pads, such as lateral interconnect lines and VIA contacts, embedded in one or more ILD layers. The interconnect lines and VIA contacts in the interconnect layer can include conductive materials including, but not limited to, W, Co, Cu, or Al, silicides, or any combination thereof. The ILD layers in the interconnect layer can include dielectric materials including, but not limited to, silicon oxide, silicon nitride, silicon oxynitride, low-k dielectrics, or any combination thereof. In some implementations, the interconnect structures in the interconnect layer can further include a silicide layer surrounded by an adhesive layer (e.g., TiN), etc. In some implementations, the interconnect structures in the interconnect layer may further include a spacer (e.g., a dielectric layer) to electrically separate the conductive materials.

Similar to the first semiconductor structure 510, the second semiconductor structure 520 of 3D memory device 500A can also include a bonding layer at bonding interface 515. Bonding layer can include a plurality of bonding contacts and dielectrics electrically isolating bonding contacts. Bonding contacts can include conductive materials including, but not limited to, W, Co, Cu, Al, silicides, or any combination thereof. The remaining area of bonding layer can be formed with dielectrics including, but not limited to, silicon oxide, silicon nitride, silicon oxynitride, low-k dielectrics, or any combination thereof. Bonding contacts and surrounding dielectrics in the bonding layer can be used for hybrid bonding. Bonding contacts of the first semiconductor structure 510 are in contact with bonding contacts of the second semiconductor structure 520 at bonding interface 515, according to some implementations.

As shown in FIG. 5A, the second semiconductor structure 520 can be bonded on top of the first semiconductor structure 510 in a face-to-face manner at bonding interface 515. In some implementations, bonding interface 515 is a result of hybrid bonding, and is the place at which the bonding layer of the first semiconductor structure 510 and the bonding layer of the second semiconductor structure 520 are met and bonded. The bonding contacts of the bonding layers of the first and second semiconductor structures 510 and 520 can be in electrical contact with each other, such that the one or more peripheral circuits in the second semiconductor structure 520 can be coupled with the memory cell array 514 in the first semiconductor structure 510.

As shown in FIG. 5A, in some implementations, the 3D memory device 500A can further include a pad-out structure 530 on the back side of the semiconductor layer 540. The pad-out structure 530 can include one or more conductive pads 535 and an interconnect layer comprising interconnect structures coupled between the conductive pads 535 and the third contact structure 569 to transfer electrical signals. The interconnect layer of the pad-out structure 530 can include a plurality of interconnects, including lateral interconnect lines and VIA contacts, formed by any suitable BEOL method. The interconnect layer of the pad-out structure 530 can further include one or more ILD layers in which the interconnect lines and VIA contacts can form. The interconnect lines and VIA contacts in the interconnect layer can include conductive materials including, but not limited to, W, Co, Cu, or Al, silicides, or any combination thereof. The ILD layers in the interconnect layer can include dielectric materials including, but not limited to, silicon oxide, silicon nitride, silicon oxynitride, low-k dielectrics, or any combination thereof.

Although exemplary 3D memory structures 400A and 500A are shown in FIGS. 4A-4B and 5A-5B, it is understood that by varying the relative positions of first and second semiconductor structures and the usage of various interconnects, contacts, and/or the pad-out locations (e.g., through first semiconductor structure and/or second semiconductor structure), any other suitable architectures of 3D memory devices may be applicable in the present disclosure without further detailed elaboration.

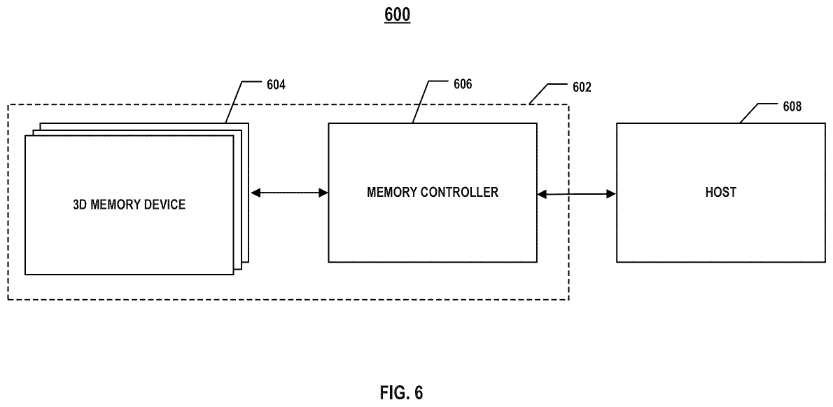

FIG. 6 illustrates a block diagram of an exemplary system 600 having a 3D memory device, according to some aspects of the present disclosure. System 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, system 600 can include a host 608 and a memory system 602 having one or more 3D memory devices 604 and a memory controller 606. Host 608 can be a processor of an electronic device, such as a central processing unit (CPU), or a system-on-chip (SoC), such as an application processor (AP). Host 608 can be configured to send or receive data to or from 3D memory device 604.

3D memory device 604 can be any 3D memory devices disclosed herein, such as 3D memory devices 100/400A/500A, shown in FIGS. 1, 4A-4B and 5A-5B. In some implementations, each 3D memory device 604 includes a NAND Flash memory and/or a DRAM memory. Memory controller 606 (a.k.a., a controller circuit) is coupled to 3D memory device 604 and host 608 and is configured to control 3D memory device 604, according to some implementations. Memory controller 606 can manage the data stored in 3D memory device 604 and communicate with host 608. In some implementations, memory controller 606 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed for operating in a high duty-cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions may be performed by memory controller 606 as well, for example, formatting 3D memory device 604. Memory controller 606 can communicate with an external device (e.g., host 608) according to a particular communication protocol. For example, memory controller 606 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

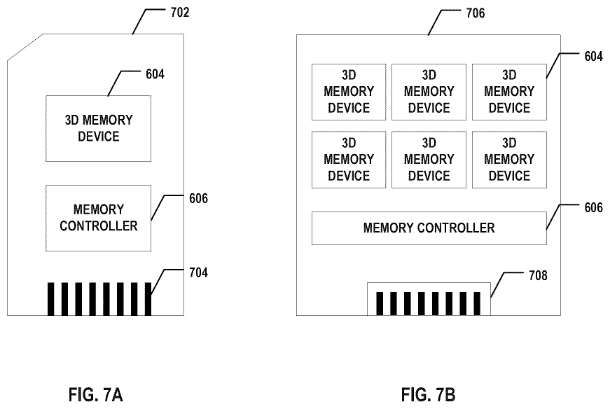

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 7A, memory controller 606 and a single 3D memory device 604 may be integrated into a memory card 702. Memory card 702 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 702 can further include a memory card connector 704 electrically coupling memory card 702 with a host (e.g., host 608 in FIG. 6). In another example as shown in FIG. 7B, memory controller 606 and multiple 3D memory devices 604 may be integrated into an SSD 706. SSD 706 can further include an SSD connector 708 electrically coupling SSD 706 with a host (e.g., host 608 in FIG. 6). In some implementations, the storage capacity and/or the operation speed of SSD 706 is greater than those of memory card 702.

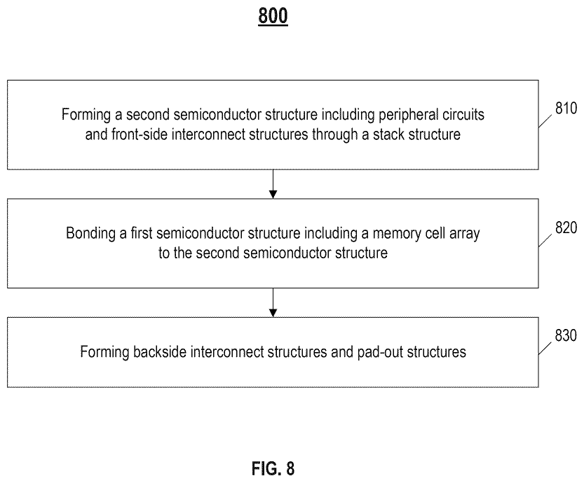

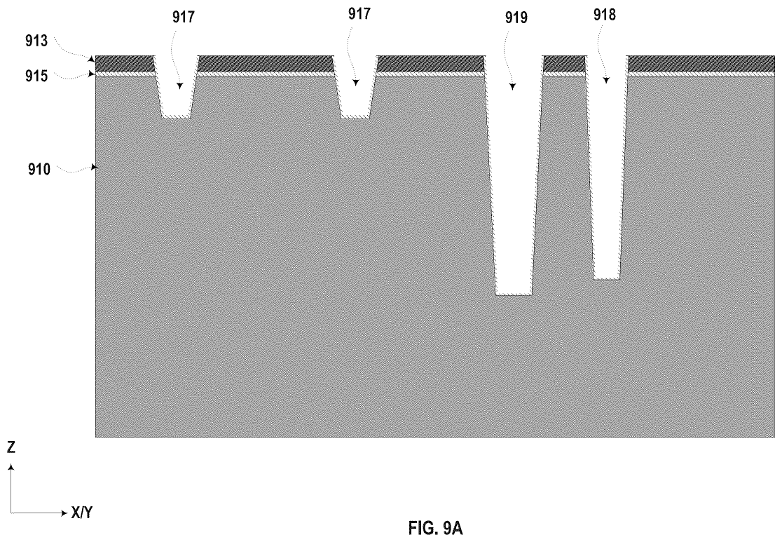

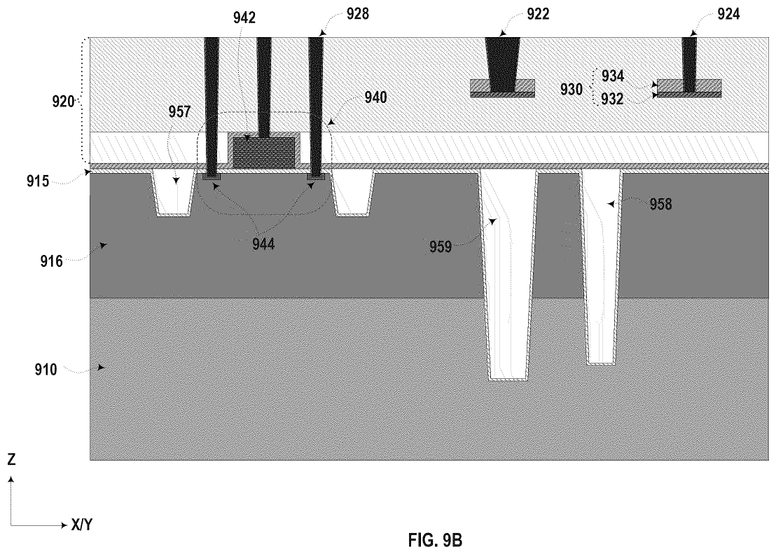

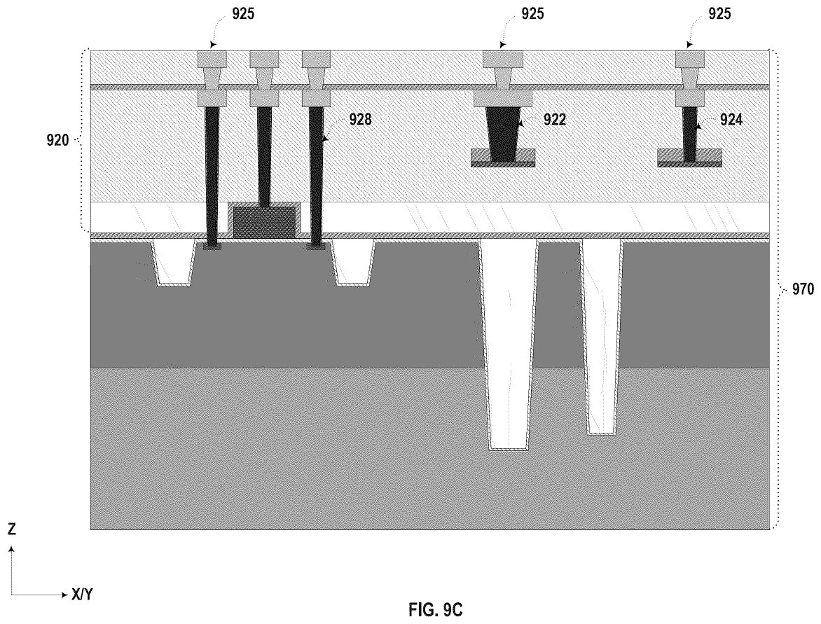

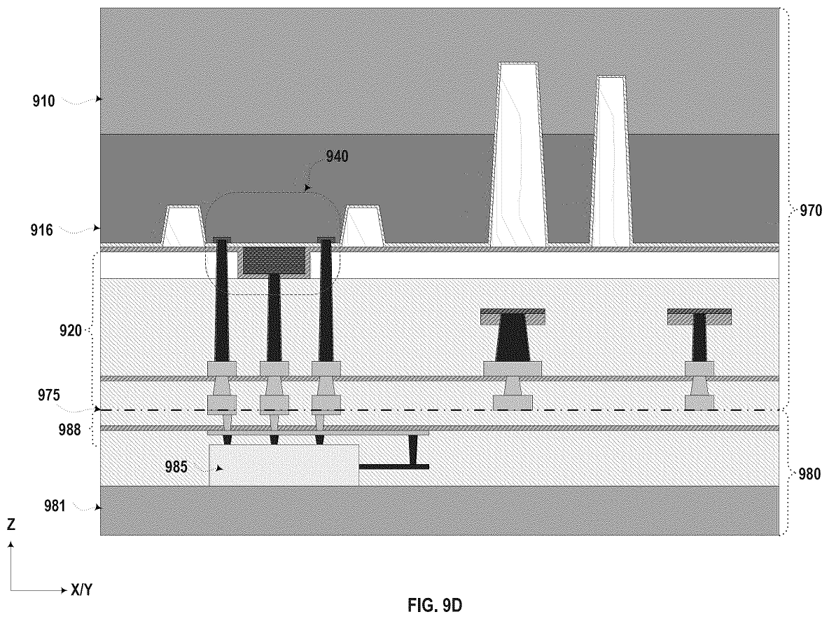

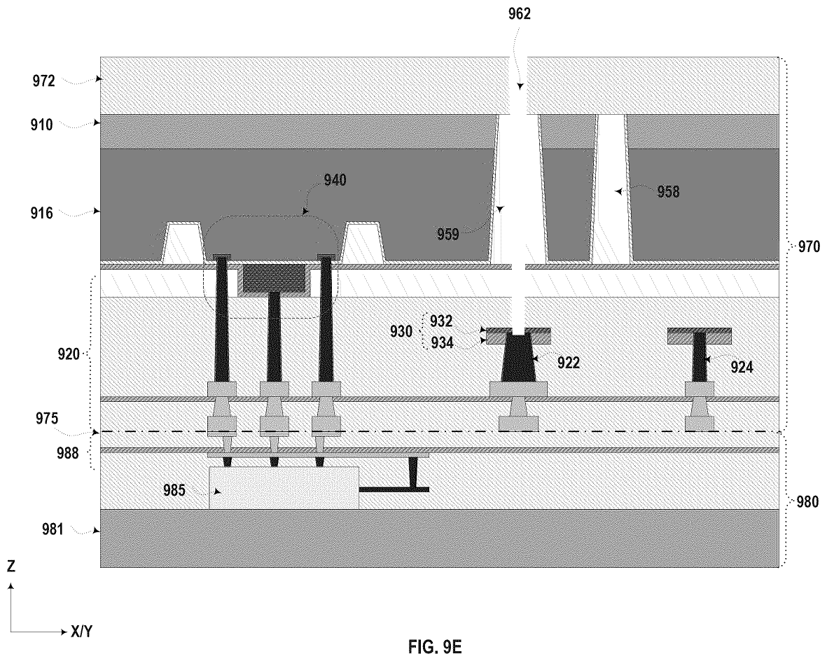

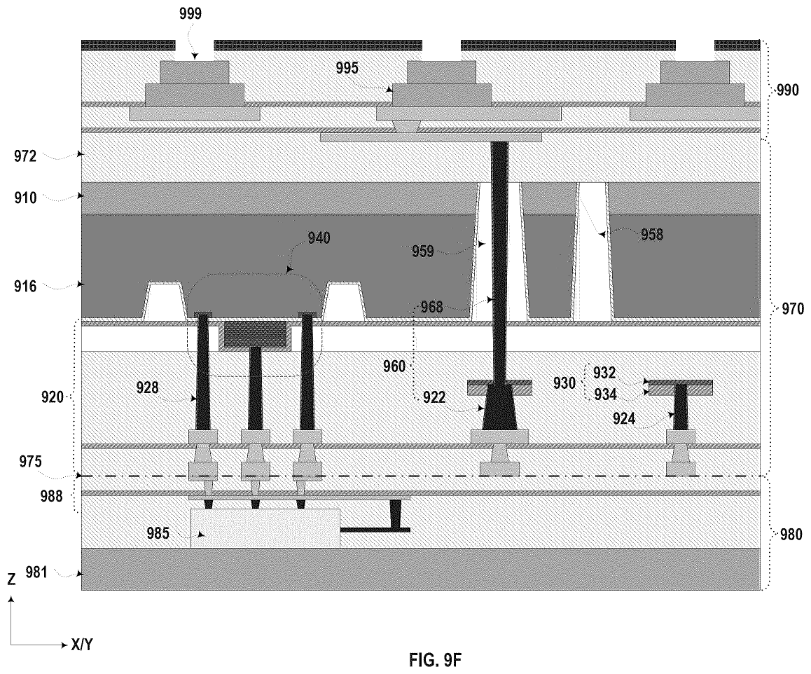

Referring to FIG. 8, a flow diagram of an exemplary method for forming a 3D memory device is illustrated in accordance with some implementations of the present disclosure. It should be understood that the operations shown in FIG. 8 are not exhaustive and that other operations can be performed as well before, after, or between any of the illustrated operations. Further, some of the operations may be performed simultaneously, or in a different order than shown in FIG. 8. FIGS. 9A-9F illustrate schematic cross-sectional views of an exemplary 3D memory device at certain fabricating stages of the method shown in FIG. 8 according to some implementations of the present disclosure.

Referring to FIG. 8, method 800 can start at operation 810, in which a second semiconductor structure including peripheral circuits can be formed. In some implementations, the peripheral circuits include a plurality of transistors. The transistors are formed at a first side of a semiconductor layer. In some implementations, first isolation structures, second isolation structures, and insulating structures can be formed in the semiconductor layer. The second semiconductor structure further includes contact structures on the first side of the semiconductor layer. FIGS. 9A-9C illustrate schematic cross-sectional views of an exemplary 3D structure at certain fabricating stages of the operation 810, according to some implementations of the present disclosure.

In some implementations, operation 810 can include forming trenches in a semiconductor layer. The semiconductor layer 910 can include Si, SiGe, GaA, Ge, or any other suitable semiconductor materials. In some implementations, the semiconductor layer 910 can be monocrystal silicon layer. As shown in FIG. 9A, the semiconductor layer 910 can be patterned to form a plurality of first trenches 917, second trenches 918, and third trenches in an upper portion of the semiconductor layer 910. In some implementations, the depth of the first trenches 917 can be less than the depths of the second trenches 918 and the third trenches 919. In some implementations, the first trenches 917, the second trenches 918, and the third trenches 919 can be formed by forming a mask layer 913 over an oxide layer 915 on the semiconductor layer 910 and patterning the mask layer 913 using, e.g., photolithography, to form openings corresponding to the multiple trenches in the patterned mask layer 913. One or more suitable etching processes, e.g., dry etch and/or wet etch, can be performed to remove portions of semiconductor layer 910 exposed by the openings until the first trenches 917, the second trenches 918, and the third trenches 919 reach the desired depths, respectively.

The mask layer 913 can be removed after the formation of the first trenches 917, the second trenches 918, and the third trenches 919. As shown in FIG. 9B, an oxide layer, an optional protection layer, and a filling material can be deposited to fill the first trenches 917, the second trenches 918, and the third trenches 919 to form the first isolation structures 957, the second isolation structures 958, and the insulating structures 959. The filling material can include any suitable dielectric materials, such as silicon oxide, silicon nitride, silicon oxynitride, or high-k dielectrics. In some implementations, the first isolation structures 957 can be shallow trench isolations (STIs), the second isolation structures 958 can be an enclosed deep trench isolation (DTI), and the insulating structures 959 can be located either within or outside of the second isolation structures 958.

In some implementations, operation 810 can further include forming doped regions in the semiconductor layer. As shown in FIG. 9B, a lightly doped semiconductor layer 916 can be formed in the upper portion of the semiconductor layer 910. In some implementations, the depth of the lightly doped semiconductor layer 916 can be greater than the height of the first isolation structures 957 but less than the thicknesses of the second isolation structures 958 and insulating structures 959. In some implementations, a first amount of n-type or p-type impurities (dopants) can be introduced into an upper portion of the semiconductor layer 910 to create an n-type or p-type doped region having a first dopant concentration. As shown in FIG. 9B, forming transistors 940 can further include forming a plurality of heavily doped regions in the semiconductor layer 910. In some implementations, a second amount of the same type of impurities (dopants) can be introduced into multiple portions of the lightly doped semiconductor layer 916 to create heavily doped regions having a second dopant concentration greater than the first dopant concentration. The lightly doped semiconductor layer 916 can be used as the channels of the formed transistors 940. The heavily doped regions can be used as the source/drain regions 944 of the transistors 940. The doping processes of forming the lightly doped semiconductor layer 916 and the heavily doped regions can include one or more of ion implantation, diffusion, in-situ doping, activation annealing, etc.

In some implementations, operation 810 can further include forming gate structures 942 of the transistors 940 on a first side of the lightly doped semiconductor layer 916. In some implementations, portions of the oxide layer 915 can be used as a gate dielectric layer. A conductive gate material can be deposited on the oxide layer 915 between the heavily doped regions 944 to form the gate electrodes of the transistors 940. The gate electrodes can include any suitable conductive materials, such as polysilicon, metals (e.g., tungsten (W), copper (Cu), aluminum (Al), etc.), metal compounds (e.g., TiN, tantalum nitride (TaN), etc.), or silicides.

As shown in FIG. 9B, operation 810 can further include forming an interconnect layer 920. In some implementations, forming the interconnect layer 920 can include forming one or more ILD layers on the first isolation structures 957, the second isolation structures 958, the insulating structures 959, and the gate structures 942 of the transistors 940. In some implementations, the first isolation structures 957 can be used as the shallow trench isolations (STIs) to separate adjacent transistors 940. In some implementations, operation 810 can further include forming one or more stack structures 930 in the IDL layers and aligned with the insulating structures 959. The stack structure 930 can include a TiN layer 932 and a SiN layer 934. In some implementations, forming the interconnect layer 920 can include forming a plurality of contact structures 922, 924, and 928 in the one or more ILD layers. In some implementations, the contact structures 922 and 924 can extend through the SiN layer 934 without extending through the TiN layer 932. In some implementations, the contact structures 928 can be in contact with the gate structures 942 and the source/drain regions 944 of the transistors 940.

As shown in FIG. 9C, forming the interconnect layer 920 can further include forming a bonding layer including a plurality of bonding contacts 925. In some implementations, forming the interconnect layer 920 can include forming one or more ILD layers, forming vertical openings (e.g., by wet etching and/or dry etching) in the one or more ILD layers, and filling the openings with conductor materials using ALD, CVD, PVD, any other suitable processes, or any combination thereof to form the contact structures and bonding contacts. The contact structures and the bonding contacts can include interconnect lines and VIA contacts including conductive materials including, but not limited to, W, Co, Cu, or Al, silicides, or any combination thereof. The ILD layers in the interconnect layer 920 can include dielectric materials including, but not limited to, silicon oxide, silicon nitride, silicon oxynitride, low-k dielectrics, or any combination thereof.

In some implementations, each contact structure in the interconnect layer 920 can include multiple sub-contacts formed in the multiple ILD layers. For example, the multiple sub-contacts can include one or more contacts, single-layer/multi-layer vias, conductive lines, plugs, pads, etc., formed in multiple contact-forming processes. For example, fabrication processes to form multiple sub-contacts can include forming one or more conductive layers and one or more contact layers in the corresponding ILD layers. The conductive layers and the conductor contact layers can be formed by any suitable known MEOL or BEOL methods. By connecting the transistors 940 through the interconnect layer 920, the second semiconductor structure 970 including one or more peripheral circuits can be formed.

Referring back to FIG. 8, method 800 proceeds to operation 820, in which a first semiconductor structure including a memory cell array can be bonded to the second semiconductor structure including the peripheral circuits. FIG. 9D illustrates a schematic cross-sectional view of the exemplary 3D structure after operation 820, according to some implementations of the present disclosure.

In some implementations, as shown in FIG. 9D, a first semiconductor structure 980 including a memory cell array 985 on a substrate 981, and an interconnect layer 988 on the memory cell array 985 can be provided. In some implementations, the substrate 981 can be any suitable semiconductor substrate having any suitable structure, such as a monocrystalline single-layer substrate, a polycrystalline silicon (polysilicon) single-layer substrate, a polysilicon and metal multi-layer substrate, etc. In some implementations, memory cell array 985 can be any suitable type of memory cell array, such as NAND Flash memory cell array, DRAM cell array, NOR Flash memory cell array, PCM cell array, FRAM cell array, resistive memory cell array, magnetic memory cell array, STT memory cell array, etc.

In some implementations, the interconnect layer 988 is formed above the memory cell array 985 to transfer electrical signals from/to the memory cell array 985. The interconnect layer 988 can include a plurality of interconnects, including lateral interconnect lines, VIA contacts, and bonding contacts, formed by any suitable MEOL or BEOL processes. The interconnect layer 988 can further include one or more ILDs in which the interconnects can form. The interconnects in the interconnect layer can include conductive materials including, but not limited to, W, Co, Cu, or Al, silicides, or any combination thereof. The ILD layers in the interconnect layer 988 can include dielectric materials including, but not limited to, silicon oxide, silicon nitride, silicon oxynitride, low-k dielectrics, or any combination thereof.

As shown in FIG. 9D, the first semiconductor structure 980 and the second semiconductor structure 970 can be bonded in a face-to-face manner. That is, the second semiconductor structure 970 can be flipped upside down, and bonded to the first semiconductor structure 980. The bonding can include hybrid bonding. As such, the first semiconductor structure 980 and the second semiconductor structure 970 can be bonded together in a face-to-face manner at bonding interface 975, according to some implementations. In some implementations, a treatment process, e.g., a plasma treatment, a wet treatment, and/or a thermal treatment, is applied to the bonding surfaces of the first semiconductor structure 980 and the second semiconductor structure 970 prior to the bonding. After the bonding, corresponding bonding contacts 925 in the interconnect layer 920 of the second semiconductor structure 970 and the bonding contacts in the interconnect layer 988 of the first semiconductor structure 980 are aligned and in contact with one another, such that memory cell array 985 can be electrically connected to the transistors 940 of the peripheral circuits.

Referring back to FIG. 8, method 800 proceeds to operation 830, in which the semiconductor layer in the second semiconductor structure can be thinned, back-side interconnect structures and pad-out structures can be formed. FIGS. 9E-9F illustrate schematic cross-sectional views of an exemplary 3D structure at certain fabricating stages of the operation 830, according to some implementations of the present disclosure.

As shown in FIG. 9E, the semiconductor layer 910 can be thinned from the backside of the second semiconductor structure 970 to expose the second isolation structures 958 and the insulating structures 959. An IDL layer 972 can be formed to cover the remaining portion of the semiconductor layer 910, the second isolation structures 958 and the insulating structures 959. In some implementations as shown in FIG. 9F, a contact structure 968 can be formed to penetrate the semiconductor layer 910 and the lightly doped semiconductor layer 916 by extending through the insulating structure 959 from the second side (i.e., backside) of the semiconductor layer 910. As shown in FIG. 9E, an opening 962 can be formed in the IDL layer 972, the insulating structure 959, the one or more IDL layers in the interconnect layer 920, and the TiN layer 932 of the stack structure 930, to expose the contact structure 922. As shown in FIG. 9F, a conductive material can be filled into the opening 962 to form the contact structure 968. In some implementations, the contact structure 968 and the contact structure 922 constitute a through interconnect structure 960 extending through the insulating structure 959.

In some implementations as shown in FIG. 9F, a pad-out structure 990 can include an interconnect layer comprising interconnect structures 995 embedded in one or more ILD layers and in contact with the through interconnect structures 960. In some implementations, the interconnect structures 995 can include any suitable conductive materials including, but not limited to, W, Co, Cu, Al, doped silicon, silicides, or any combination thereof. In some implementations, the pad-out structure 990 can further include conductive pads 999 in contact with the interconnect structures 995. In some implementations, the one or more ILD layers can include one or more layers of dielectric materials such as silicon oxide, silicon nitride, silicon oxynitride, or any combination thereof, and can be formed by one or more thin film deposition processes, such as ALD, CVD, PVD, any other suitable processes, or any combination thereof. The conductive pads 999 can include conductive materials including, but not limited to, W, Co, Cu, Al, doped silicon, silicides, or any combination thereof.

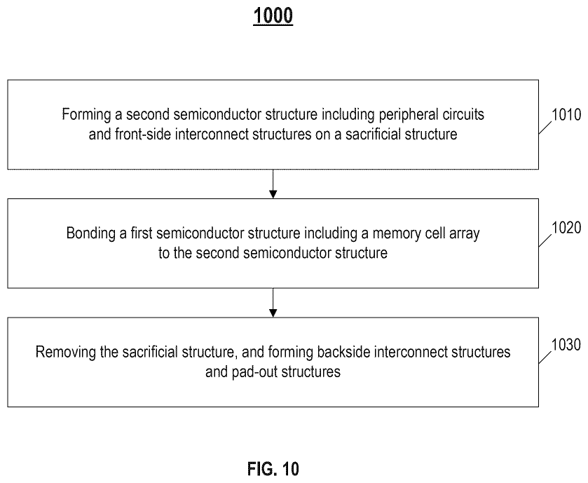

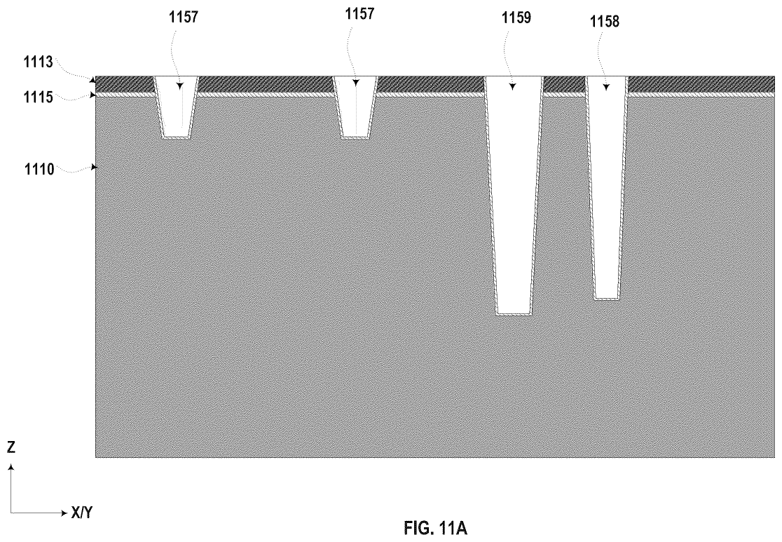

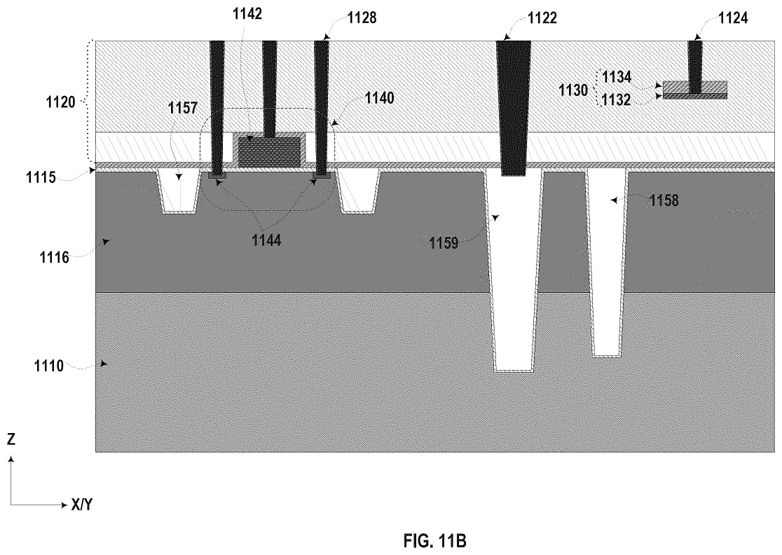

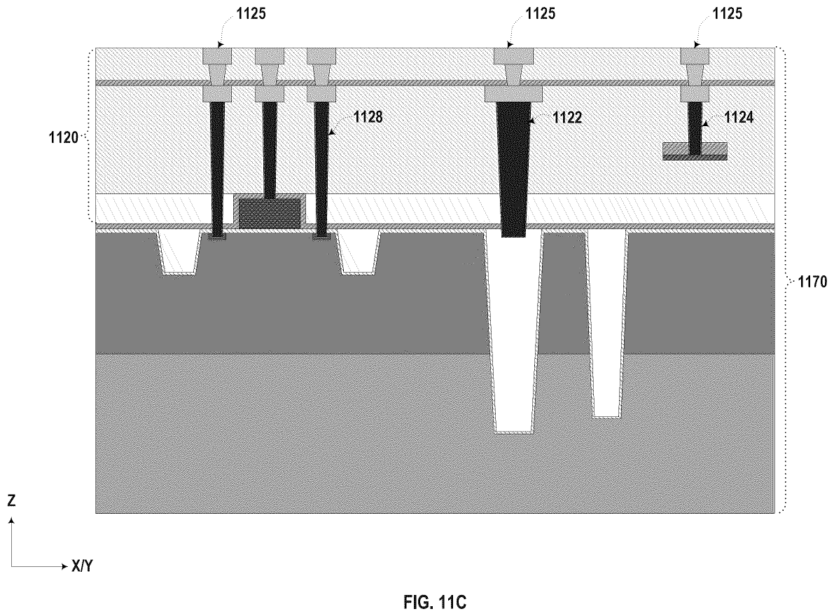

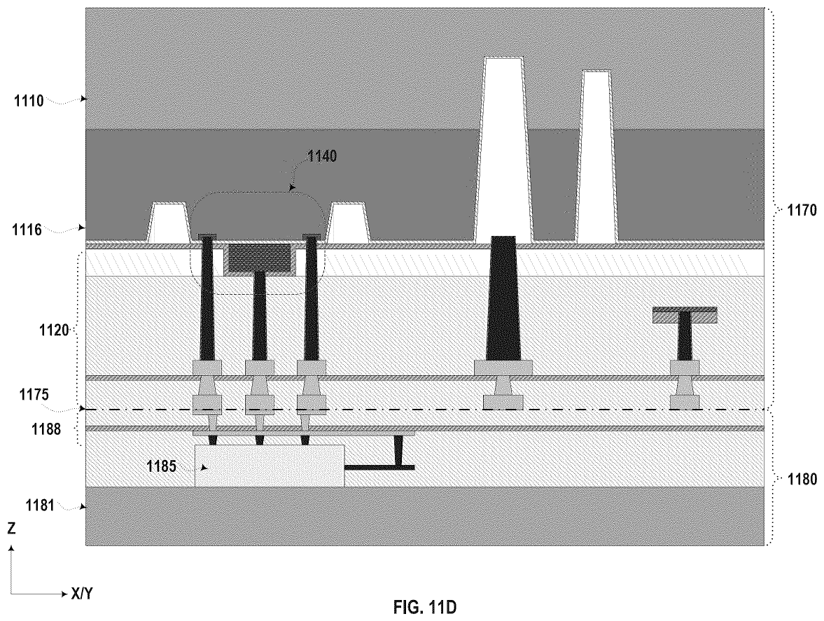

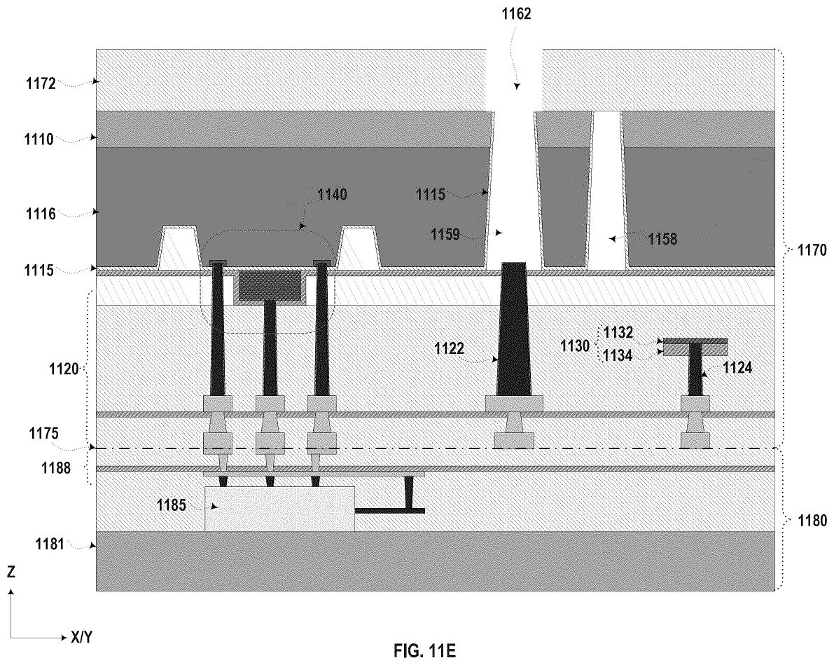

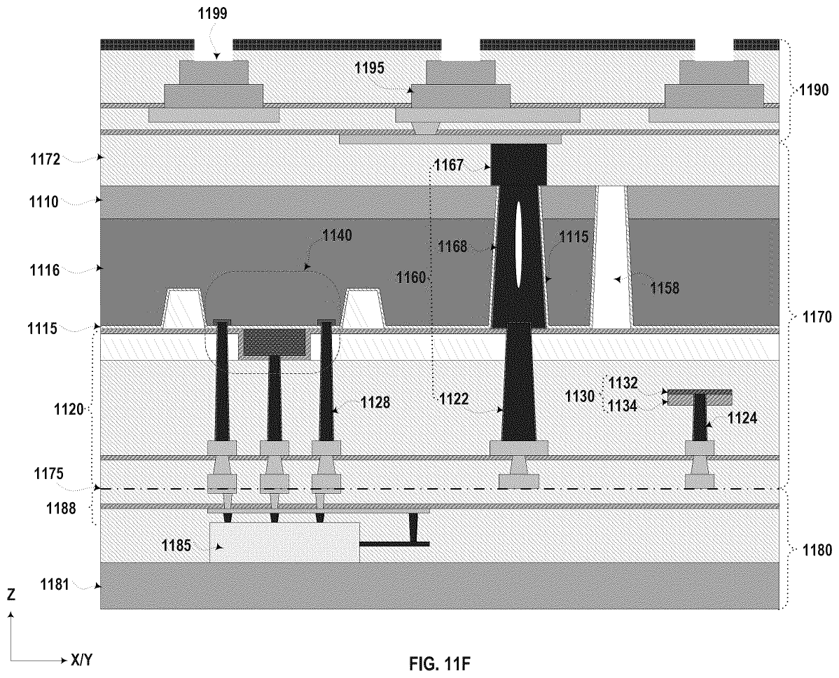

Referring to FIG. 10, a flow diagram of an exemplary method for forming a 3D memory device is illustrated in accordance with some implementations of the present disclosure. It should be understood that the operations shown in FIG. 10 are not exhaustive and that other operations can be performed as well before, after, or between any of the illustrated operations. Further, some of the operations may be performed simultaneously, or in a different order than shown in FIG. 10. FIGS. 11A-11F illustrate schematic cross-sectional views of an exemplary 3D memory device at certain fabricating stages of the method shown in FIG. 10 according to some implementations of the present disclosure.

Referring to FIG. 10, method 1000 can start at operation 1010, in which a second semiconductor structure including peripheral circuits can be formed. In some implementations, the peripheral circuits include a plurality of transistors. The transistors are formed at a first side of a semiconductor layer. In some implementations, isolation structures and insulating structures can be formed in the semiconductor layer. The second semiconductor structure further includes contact structures on the first side of the semiconductor layer. FIGS. 11A-11C illustrate schematic cross-sectional views of an exemplary 3D structure at certain fabricating stages of the operation 1010, according to some implementations of the present disclosure.

In some implementations, operation 1010 can include forming trenches in a semiconductor layer. The semiconductor layer 1110 can include Si, SiGe, GaA, Ge, or any other suitable semiconductor materials. In some implementations, semiconductor layer 1110 can be monocrystal silicon layer. As shown in FIG. 11A, the semiconductor layer 1110 can be patterned to form a plurality of first trenches, second trenches, and third trenches in an upper portion of the semiconductor layer 1110. In some implementations, the depth of the first trenches can be less than the depths of the second trenches and the third trenches. In some implementations, the first trenches, the second trenches, and the third trenches can be formed by forming a mask layer 1113 over an oxide layer 1115 on the semiconductor layer 1110 and patterning the mask layer 1113 using, e.g., photolithography, to form openings corresponding to the multiple trenches in the patterned mask layer 1113. One or more suitable etching processes, e.g., dry etch and/or wet etch, can be performed to remove portions of semiconductor layer 1110 exposed by the openings until the first trenches, the second trenches, and the third trenches reach the desired depths, respectively. The mask layer 1113 can be removed after the formation of the first trenches and the second trenches. As shown in FIG. 11A, an oxide layer can be deposited to cover the sidewalls and the bottoms of the first trenches, the second trenches, and the third trenches. A first dielectric material can be filled into the first trenches to form first isolation structures 1157 (e.g., STIs), and a second dielectric material can be filled into the second trenches and the third trenches to form second isolation structure 1158 (e.g., enclosed DTIs) and sacrificial structures 1159. In some implementations, the first dielectric material is different from the second dielectric material.

In some implementations, operation 1010 can further include forming doped regions in the semiconductor layer. As shown in FIG. 11B, a lightly doped semiconductor layer 1116 can be formed in the upper portion of the semiconductor layer 1110. In some implementations, the depth of the lightly doped semiconductor layer 1116 can be greater than the height of the first isolation structures 1157 but less than the thicknesses of the second isolation structures 1158 and the sacrificial structures 1159. In some implementations, a first amount of n-type or p-type impurities (dopants) can be introduced into an upper portion of the semiconductor layer 1110 to create an n-type or p-type doped region having a first dopant concentration. As shown in FIG. 11B, forming transistors 1140 can further include forming a plurality of heavily doped regions in the semiconductor layer 1110. In some implementations, a second amount of the same type of impurities (dopants) can be introduced into multiple portions of the lightly doped semiconductor layer 1116 to create heavily doped regions having a second dopant concentration greater than the first dopant concentration. The lightly doped semiconductor layer 1116 can be used as the channels of the formed transistors 1140. The heavily doped regions can be used as the source/drain regions 1144 of the transistors 1140. The doping processes of forming the lightly doped semiconductor layer 1116 and the heavily doped regions can include one or more of ion implantation, diffusion, in-situ doping, activation annealing, etc.

In some implementations, operation 1010 can further include forming gate structures 1142 of the transistors 1140 on a first side of the lightly doped semiconductor layer 1116. In some implementations, portions of the oxide layer 1115 can be used as a gate dielectric layer. A conductive gate material can be deposited on the oxide layer 1115 between the heavily doped regions 1144 to form the gate electrodes of the transistors 1140. The gate electrodes can include any suitable conductive materials, such as polysilicon, metals (e.g., W, Cu, Al, etc.), metal compounds (e.g., TiN, TaN, etc.), or silicides.

As shown in FIG. 11B, operation 1010 can further include forming an interconnect layer 1120. In some implementations, forming the interconnect layer 1120 can include forming one or more ILD layers on the first isolation structures 1157, the second isolation structures 1158, the sacrificial structures 1159, and the gate structures 1142 of the transistors 1140. In some implementations, the first isolation structures 1157 can be used as the STIs to separate adjacent transistors 1140. In some implementations, operation 1010 can further include forming one or more stack structures 1130 in the IDL layers. The stack structure 1130 can include a TiN layer 1132 and a SiN layer 1134. In some implementations, forming the interconnect layer 1120 can include forming a plurality of contact structures 1122, 1124, and 1128 in the one or more ILD layers. In some implementations, the contact structures 1122, 1124, and 1128 can include a first conductive layer surrounded by a second conductive layer. For example, the first conductive layer can be a metal (e.g., W, Co, Cu, or Al) layer, and the second conductive layer can be a TiN layer. In some implementations, the contact structures 1122 can extend into the sacrificial structures 1159. In some implementations, the contact structures 1124 can extend through the SiN layer 1134 without extending through the TiN layer 1132. In some implementations, the contact structures 1128 can be in contact with the gate structures 1142 and the source/drain regions 1144 of the transistors 1140.

As shown in FIG. 11C, forming the interconnect layer 1120 can further include forming a bonding layer including a plurality of bonding contacts 1125. In some implementations, forming the interconnect layer 1120 can include forming one or more ILD layers, forming vertical openings (e.g., by wet etching and/or dry etching) in the one or more ILD layers, and filling the openings with conductor materials using ALD, CVD, PVD, any other suitable processes, or any combination thereof to form the contact structures and bonding contacts. The contact structures and the bonding contacts can include interconnect lines and VIA contacts including conductive materials including, but not limited to, W, Co, Cu, or Al, silicides, or any combination thereof. The ILD layers in the interconnect layer 1120 can include dielectric materials including, but not limited to, silicon oxide, silicon nitride, silicon oxynitride, low-k dielectrics, or any combination thereof.

In some implementations, each contact structure in the interconnect layer 1120 can include multiple sub-contacts formed in the multiple ILD layers. For example, the multiple sub-contacts can include one or more contacts, single-layer/multi-layer vias, conductive lines, plugs, pads, etc., formed in multiple contact-forming processes. For example, fabrication processes to form multiple sub-contacts can include forming one or more conductive layers and one or more contact layers in the corresponding ILD layers. The conductive layers and the conductor contact layers can be formed by any suitable known MEOL or BEOL methods. By connecting the transistors 1140 through the interconnect layer 1120, the second semiconductor structure 1170 including one or more peripheral circuits can be formed.

Referring back to FIG. 10, method 1000 proceeds to operation 1020, in which a first semiconductor structure including a memory cell array can be bonded to the second semiconductor structure including the peripheral circuits. FIG. 11D illustrates a schematic cross-sectional view of the exemplary 3D structure after operation 1020, according to some implementations of the present disclosure.

In some implementations, as shown in FIG. 11D, a first semiconductor structure 1180 including a memory cell array 1185 on a substrate 1181, and an interconnect layer 1188 on the memory cell array 1185 can be provided. In some implementations, the substrate 1181 can be any suitable semiconductor substrate having any suitable structure, such as a monocrystalline single-layer substrate, a polycrystalline silicon (polysilicon) single-layer substrate, a polysilicon and metal multi-layer substrate, etc. In some implementations, memory cell array 1185 can be any suitable type of memory cell array, such as NAND Flash memory cell array, DRAM cell array, NOR Flash memory cell array, PCM cell array, FRAM cell array, resistive memory cell array, magnetic memory cell array, STT memory cell array, etc.

In some implementations, the interconnect layer 1188 is formed above the memory cell array 1185 to transfer electrical signals from/to the memory cell array 1185. The interconnect layer 1188 can include a plurality of interconnects, including lateral interconnect lines, VIA contacts, and bonding contacts, formed by any suitable MEOL or BEOL processes. The interconnect layer 1188 can further include one or more ILDs in which the interconnects can form. The interconnects in the interconnect layer can include conductive materials including, but not limited to, W, Co, Cu, or Al, silicides, or any combination thereof. The ILD layers in the interconnect layer 1188 can include dielectric materials including, but not limited to, silicon oxide, silicon nitride, silicon oxynitride, low-k dielectrics, or any combination thereof.

As shown in FIG. 11D, the first semiconductor structure 1180 and the second semiconductor structure 1170 can be bonded in a face-to-face manner. That is, the second semiconductor structure 1170 can be flipped upside down, and bonded to the first semiconductor structure 1180. The bonding can include hybrid bonding. As such, the first semiconductor structure 1180 and the second semiconductor structure 1170 can be bonded together in a face-to-face manner at bonding interface 1175, according to some implementations. In some implementations, a treatment process, e.g., a plasma treatment, a wet treatment, and/or a thermal treatment, is applied to the bonding surfaces of the first semiconductor structure 1180 and the second semiconductor structure 1170 prior to the bonding. After the bonding, corresponding bonding contacts 1125 in the interconnect layer 1120 of the second semiconductor structure 1170 and the bonding contacts in the interconnect layer 1188 of the first semiconductor structure 1180 are aligned and in contact with one another, such that memory cell array 1185 can be electrically connected to the transistors 1140 of the peripheral circuits.

Referring back to FIG. 10, method 1000 proceeds to operation 1030, in which the semiconductor layer in the second semiconductor structure can be thinned, back-side interconnect structures and pad-out structures can be formed. FIGS. 11E-11F illustrate schematic cross-sectional views of an exemplary 3D structure at certain fabricating stages of the operation 1030, according to some implementations of the present disclosure.

As shown in FIG. 11E, the semiconductor layer 1110 can be thinned from the backside of the second semiconductor structure 1170 to expose the second isolation structures 1158 and the sacrificial structures 1159. An IDL layer 1172 can be formed to cover the remaining portion of the semiconductor layer 1110 and the exposed second isolation structures 1158 and sacrificial structures 1159. As shown in FIG. 11E, an opening 1162 can be formed in the IDL layer 1172 to expose the sacrificial structure 1159. The sacrificial material in the sacrificial structure 1159 can be removed by using any suitable etching process to form a cavity surrounded by the oxide layer 1115. As shown in FIG. 11F, a conductive material can be filled into the cavity to form a via contact 1168, and be filled into the opening 1162 to form the contact structure 1167. In some implementations, the contact structure 1167, the via contact 1168, and the contact structure 1122 constitute a through interconnect structure 1160 extending through the semiconductor layer 1110 and the lightly doped semiconductor layer 1116.

In some implementations as shown in FIG. 11F, a pad-out structure 1190 can include an interconnect layer comprising interconnect structures 1195 embedded in one or more ILD layers and in contact with the through interconnect structures 1160. In some implementations, the interconnect structures 1195 can include any suitable conductive materials including, but not limited to, W, Co, Cu, Al, doped silicon, silicides, or any combination thereof. In some implementations, the pad-out structure 1190 can further include conductive pads 1199 in contact with the interconnect structures 1195. In some implementations, the one or more ILD layers can include one or more layers of dielectric materials such as silicon oxide, silicon nitride, silicon oxynitride, or any combination thereof, and can be formed by one or more thin film deposition processes, such as ALD, CVD, PVD, any other suitable processes, or any combination thereof. The conductive pads 1199 can include conductive materials including, but not limited to, W, Co, Cu, Al, doped silicon, silicides, or any combination thereof.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A memory device, comprising:
a first semiconductor structure comprising an array of memory cells; and
a second semiconductor structure including peripheral circuits on the first semiconductor structure, and comprising:
transistors at a first side of a semiconductor layer,
first isolation structures in the semiconductor layer and between the transistors,
an insulating structure in the semiconductor layer and on a lateral side of the transistors,
a second isolation structure in the semiconductor layer and surrounding the first isolation structures and the insulating structure, and
a through interconnect structure extending through the insulating structure.

2. The memory device of claim 1, wherein:
the first semiconductor structure further comprises a first interconnect layer comprising first interconnect structures coupled with the array of memory cells; and
the second semiconductor structure further comprises a second interconnect layer comprising second interconnect structures coupled with the transistors and the through interconnect structure.

3. The memory device of claim 1, further comprising:
a pad-out structure on a second side of the semiconductor layer distant from the first semiconductor structure, and comprising a conductive pad coupled with the through interconnect structure;
wherein the transistors are on a first side of the semiconductor layer close to the first semiconductor structure.

4. The memory device of claim 1, wherein a first depth of the first isolation structures is less than a second depth of the second isolation structure.

5. The memory device of claim 1, wherein:
the semiconductor layer comprises a doped sublayer and an undoped sublayer; and
the first isolation structures are embedded in the doped sublayer.

6. The memory device of claim 1, wherein the through interconnect structure comprises:
a first contact structure extending into a stack structure from a first side close to the first semiconductor structure; and
a via contact extending through the semiconductor layer and extending into the stack structure from a second side opposite to the first side, and in contact with the first contact structure.

7. The memory device of claim 2, wherein the through interconnect structure comprises:
a first contact portion between the insulating structure and the first interconnect layer;
a via portion extending through the insulating structure, and in contact with the first contact portion; and
a second contact portion between the semiconductor layer and the second interconnect layer, and in contact with the via portion;
wherein side surfaces of the first contact portion, the via portion, and the second contact portion have offsets.

8. The memory device of claim 1, wherein:
the insulating structure comprises a protecting layer laterally surrounding the through interconnect structure and an insulating layer laterally surrounding the protecting layer.

9. The memory device of claim 1, wherein:
a lateral dimension of a first end of the through interconnect structure close to the transistors is less than a lateral dimension of a second end of the through interconnect structure distant from the transistors.

10. The memory device of claim 1, wherein the second semiconductor structure further comprises:
a transistor contact on the first side of the semiconductor layer, wherein a lateral dimension of a first end of the transistor contact in contact with the transistors is less than a lateral dimension of a second end of the transistor contact distant from the transistors.

11. A memory device, comprising:
a first semiconductor structure comprising an array of memory cells; and
a second semiconductor structure including peripheral circuits on the first semiconductor structure, and comprising:
transistors at a first side of a semiconductor layer,
first isolation structures in the semiconductor layer and between the transistors,
an insulating structure extending through the semiconductor layer and on a lateral side of the transistors,
a stack structure, and
a through interconnect structure extending through the insulating structure and the stack structure.

12. A method of forming a memory device, comprising:
forming a first semiconductor structure comprising an array of memory cells;
forming a second semiconductor structure, comprising:
forming transistors at a first side of a semiconductor layer,
forming first isolation structures in the semiconductor layer and between the transistors,
forming an insulating structure in the semiconductor layer and on a lateral side of the transistors,
forming a second isolation structure in the semiconductor layer and surrounding the first isolation structures and the insulating structure, and
forming a through interconnect structure extending through the insulating structure; and
bonding the first semiconductor structure and the second semiconductor structure.

13. The method of claim 12, wherein:
forming the first semiconductor structure further comprises forming a first interconnect layer comprising first interconnect structures coupled with the array of memory cells; and
forming the second semiconductor structure further comprises forming a second interconnect layer comprising second interconnect structures coupled with the transistors and the through interconnect structure.

14. The method of claim 13, wherein bonding the first semiconductor structure and the second semiconductor structure comprises:
hybrid bonding the first semiconductor structure with the second semiconductor structure in a vertical direction, such that first interconnect structures are coupled with the second interconnect structures and the through interconnect structure.

15. The method of claim 12, further comprising: forming a pad-out structure on a second
side of the semiconductor layer distant from the first semiconductor structure, and comprising a conductive pad coupled with the through interconnect structure,
wherein the transistors are formed on a first side of the semiconductor layer close to the first semiconductor structure.

16. The method of claim 12, wherein forming the second semiconductor structure further comprises:
forming a stack structure;
forming the through interconnect structure comprises forming a contact structure extending into the stack structure from a first side, and forming a via contact extending through the semiconductor layer and extending into the stack structure from a second side opposite to the first side, and in contact with the contact structure.

17. The method of claim 16, wherein forming the via contact comprises:
thinning the semiconductor layer to expose the insulating structure;
forming an opening extending through the insulating structure and extending into the stack structure from the second side to expose the contact structure; and
forming the via contact in the opening.

18. The method of claim 17, wherein forming the insulating structure comprises:
forming a first insulating layer;
forming a protecting layer surrounded by the first insulating layer; and
forming a second insulating layer surrounded by the protecting layer;
wherein the opening is formed to extend through the second insulating layer without damage the first insulating layer.

19. The method of claim 12, wherein forming the through interconnect structure comprises:
forming a contact structure on the first side of the semiconductor layer;
forming a sacrificial layer laterally surrounded by the insulating structure;
thinning the semiconductor layer to expose the insulating structure and the sacrificial layer;
removing the sacrificial layer to form an opening that exposes the contact structure; and
forming a via contact in the opening and in contact with the contact structure.

20. The method of claim 15, wherein forming the pad-out structure further comprises:
forming a third interconnect layer comprising third interconnect structures coupled between the conductive pad and the through interconnect structure.
